(19) United States
(12) Patent Application Publication
(10) Pub. No.: US 2026/0190640 A1
(43) Pub. Date: Jul. 2, 2026

(54) DISPLAY APPARATUS

(71) Applicant: LG Display Co., Ltd., Seoul (KR)

(72) Inventors: Seongjoo LEE, Paju-si (KR); JungSun BAEK, Paju-si (KR); Yongmin KIM, Paju-si (KR); Yosup SIM, Paju-si (KR)

(73) Assignee: LG Display Co., Ltd., Seoul (KR)

(21) Appl. No.: 19/349,084

(22) Filed: Oct. 3, 2025

(30) Foreign Application Priority Data
Dec. 27, 2024 (KR) 10-2024-0198510

(51) Int. Cl. H10K 59/122; H10K 59/124; H10K 59/35; H10K 59/38; H10K 59/80; H10K 102/00

(52) U.S. Cl. CPC H10K 59/122; H10K 59/124; H10K 59/351; H10K 59/38; H10K 59/873; H10K 2102/351

(57) ABSTRACT

A display apparatus may include: a first insulating layer in a first sub-pixel and having a first opening; a second insulating layer in a second sub-pixel and having a first groove; a first pixel electrode in the first sub-pixel, located at the first opening, and extending along a side surface of the first insulating layer; a second pixel electrode in the second sub-pixel, located on a bottom surface of the first groove, and extending along a side surface of the first groove; a first bank disposed on the first and second pixel electrodes and having a first hole overlapping and smaller than the first opening, and a second hole overlapping and smaller than the first groove; and a common electrode on first and second light-emitting layers, extending along respective side surfaces of the first and second holes of the first bank up to a top surface of the first bank.

### CROSS REFERENCE TO RELATED APPLICATION

This application claims the benefit of and priority to Korean Patent Application No. 10-2024-0198510, filed on Dec. 27, 2024, the entire contents of which are incorporated herein by reference for all purposes as if fully set forth herein.

### TECHNICAL FIELD

Embodiments of the present disclosure relate to a display apparatus.

### BACKGROUND

Display apparatuses, which display various types of information on a screen, are a core technology in the information and communication technology era, serving the role of delivering diverse information to users.

Display apparatuses may be required to provide excellent display quality and high light emission efficiency. In particular, it may be necessary for the display apparatus to maintain superior display quality when a user views the screen.

However, light reflected by identical pixels of the display apparatus may undergo constructive and destructive interference, resulting in a problem where annular mura occurs due to reflected light.

The description provided in the background section should not be considered prior art merely because it is mentioned in or associated with this section. The description provided in the background section includes information that describes one or more aspects of the subject technology, and the description provided in this section does not limit the scope of the invention.

### SUMMARY

Embodiments of the present disclosure may provide a display apparatus capable of converting reflected light causing constructive and destructive interference between pixels into reflected light causing only destructive interference.

Embodiments of the present disclosure may provide a display apparatus including a first pixel and a second pixel, in which annular mura does not occur even at a wide viewing angle.

The aspects of embodiments of the present disclosure are not limited to those described herein, and other aspects not mentioned will be clearly understood by those skilled in the art from the present disclosure.

Embodiments of the present disclosure may provide a display apparatus comprising: a substrate; a first planarization layer disposed on the substrate; a second planarization layer disposed on the first planarization layer; a first insulating layer disposed on the second planarization layer, located in a first sub-pixel area, and having a first opening; a second insulating layer disposed on the second planarization layer, located in a second sub-pixel area, and having a first groove; a first pixel electrode disposed in the first sub-pixel area, located on the second planarization layer at the first opening, and extending along an inner side surface of the first insulating layer; a second pixel electrode disposed in the second sub-pixel area, located on a bottom surface of the first groove, and extending along an inner side surface of the first groove; a first bank disposed on the first pixel electrode and the second pixel electrode and having a first hole overlapping the first opening and smaller than the first opening, and a second hole overlapping the first groove and smaller than the first groove; a first light-emitting layer disposed on the first pixel electrode; a second light-emitting layer disposed on the second pixel electrode; and a common electrode disposed on the first light-emitting layer and the second light-emitting layer, extending along respective inner side surfaces of the first hole and the second hole of the first bank up to a top surface of the first bank.

According to embodiments of the present disclosure, a display apparatus capable of suppressing annular mura even at a wide viewing angle, including a first pixel and a second pixel, may be provided.

According to embodiments of the present disclosure, by providing different distances between the substrate and the pixel electrodes in a first sub-pixel of the first pixel and a second sub-pixel of the second pixel, a display apparatus with improved reflectance visibility may be provided.

According to embodiments of the present disclosure, a display apparatus that enables low power consumption by improving reflectance visibility may be provided.

According to embodiments of the present disclosure, a display apparatus capable of exhibiting excellent luminance and color characteristics even in a side viewing angle direction may be provided, including a first sub-pixel comprising a first sub-opening and a second sub-opening, and a second sub-pixel comprising a first sub-groove and a second sub-groove.

According to embodiments of the present disclosure, a display apparatus capable of low-power driving due to excellent luminance characteristics at a side viewing angle may be provided.

The advantages of embodiments of the present disclosure are not limited to those described above, and other advantages not mentioned will be clearly understood by those skilled in the art from the present disclosure.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further features, advantages, and aspects are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 illustrates a plan view of a display apparatus according to embodiments of the present disclosure.

FIG. 2 illustrates a display apparatus according to embodiments of the present disclosure.

FIG. 3 illustrates a cross-sectional view of a display apparatus according to embodiments of the present disclosure.

FIG. 4 illustrates a cross-sectional view of a first sub-pixel and a second sub-pixel of a display apparatus according to embodiments of the present disclosure.

FIG. 5 illustrates a cross-sectional view of a first sub-pixel and a second sub-pixel of a display apparatus according to embodiments of the present disclosure.

FIG. 6 illustrates a plan view of a first sub-pixel and a second sub-pixel of a display apparatus according to embodiments of the present disclosure.

FIG. 7 illustrates a cross-sectional view of a first sub-pixel and a second sub-pixel of a display apparatus according to embodiments of the present disclosure.

FIG. 8 illustrates a plan view of a first sub-pixel and a second sub-pixel of a display apparatus according to embodiments of the present disclosure.

FIG. 9 illustrates a pixel arrangement of a display apparatus according to embodiments of the present disclosure.

FIG. 10 to FIG. 13 illustrate cross-sectional views of a first pixel and a second pixel of a display apparatus according to embodiments of the present disclosure.

FIG. 14 illustrates a cross-sectional view of a first sub-pixel and a second sub-pixel of a display apparatus according to embodiments of the present disclosure.

FIG. 15 illustrates a plan view of a first sub-pixel and a second sub-pixel of a display apparatus according to embodiments of the present disclosure.

FIG. 16 illustrates a cross-sectional view of a first sub-pixel and a second sub-pixel of a display apparatus according to embodiments of the present disclosure.

FIG. 17 illustrates a plan view of a first sub-pixel and a second sub-pixel of a display apparatus according to embodiments of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, components, electrodes, structures, transistors, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, components, electrodes, structures, transistors, sections, members, parts, regions, areas, portions, and/or the like) are described using any of the terms such as “on,” “on a top of,” “upon,” “on top of,” “over,” “under,” “above,” “upper,” “at an upper portion,” “at a upper side,” “below,” “lower,” “at a lower portion,” “at a lower side,” “beneath,” “near,” “close to,” “adjacent to,” “beside,” “next to,” “at or on a side of,” “along” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “following,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, components, electrodes, structures, transistors, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

The expression that an element (e.g., layer, film, component, electrode, structure, transistor, section, member, part, region, area, portion, or the like) “is engaged” with another element may be understood, for example, as that the element may be either directly or indirectly engaged with the another element. The term “is engaged” or similar expressions may refer to a term such as “covers,” “surrounds,” “is in contact,” “overlaps,” “crosses,” “intersects,” “is connected,” “is coupled,” “is attached,” “is adhered,” “is combined,” “is linked,” “is provided,” “is disposed,” “interacts,” or the like. The engagement may involve one or more intervening elements disposed or interposed between the element and the another element, unless otherwise specified. Further, the element may be engaged at least partially or entirely (or completely) with the another element, unless otherwise specified. Further, the element may be included in at least one of two or more elements that are engaged with each other. Similarly, the another element may be included in at least one of two or more elements that are engaged with each other. When the element is engaged with the another element, at least a portion of the element may be engaged with at least a portion of the another element. The term “with another element” or similar expressions may be understood as “another element,” or “with, to, in, or on another element,” as appropriate by the context. Similarly, the term “with each other” may be understood as “each other,” or “with, to, or on each other,” as appropriate by the context.

The phrase “through” may be understood, for example, to be at least partially through or entirely through.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally. For example, the terms “first direction,” “second direction,” and the like should not be interpreted only based on a geometrical relationship in which the respective directions are parallel, perpendicular, diagonal, or slanted with respect to each other, and may be meant as directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements. Further, “at least some,” “at least some portions,” “at least some parts,” “at least a portion,” “at least one or more portions,” “at least a part,” “at least one or more parts,” “at least some elements,” “one or more,” or the like of a plurality of elements can represent (i) one element of the plurality of elements, (ii) a portion (or a part) of the plurality of elements, (iii) one or more portions (or parts) of the plurality of elements, (iv) multiple elements of the plurality of elements, or (v) all of the plurality of elements. Moreover, “at least some,” “at least some portions,” “at least some parts,” “at least a portion,” “at least one or more portions,” “at least a part,” “at least one or more parts,” or the like of an element can represent (i) a portion (or a part) of the element, (ii) one or more portions (or parts) of the element, (iii) the element, or (iv) all portions of the element.

The expression of a first element, a second elements “and/or” a third element should be understood as any one of the first, second and third elements or as any or all combinations of the first, second and third elements. Similar interpretations apply to the use of “and/or” with two elements or with more than three elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

A phrase “substantially the same” or “nearly the same” may indicate a degree of being considered as being equivalent to each other taking into account minute differences due to errors in the manufacturing process.

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same or similar elements may be illustrated in other drawings, and like reference numerals may refer to like or similar elements unless stated otherwise. The same or similar elements may be denoted by the same reference numerals even if they are depicted in different drawings. Repetitive descriptions of the same or similar elements may be omitted for brevity, and the descriptions provided for elements in one or more figures may also apply to elements in other figures that use the same or similar reference numerals unless stated otherwise. In addition, for the convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

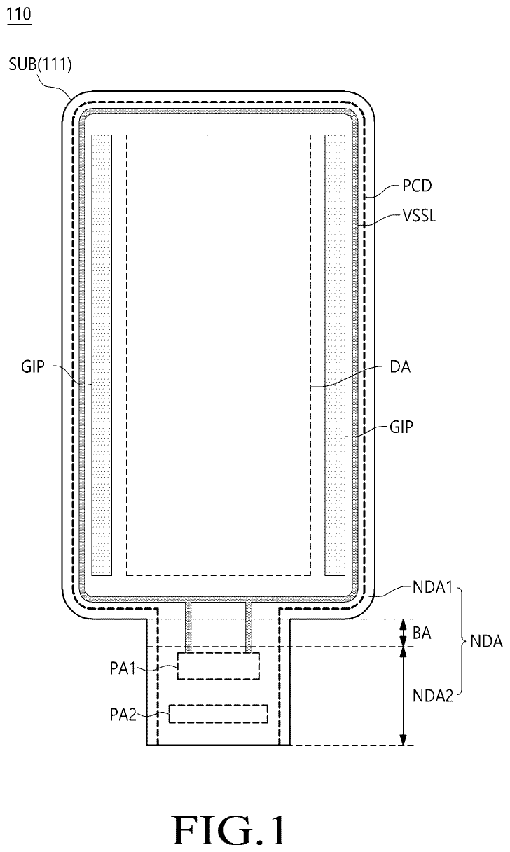

FIG. 1 is a diagram illustrating an example of a bending structure and a wiring structure in a planar structure of a display apparatus 110 according to embodiments of the present disclosure.

Referring to FIG. 1, a substrate 111 of the display apparatus 110 according to embodiments of the present disclosure may include a display area DA and a non-display area NDA. The display area DA and the non-display area NDA may also be referred to as areas of the display apparatus 110.

All wirings and all electrodes may be formed on the substrate 111. In the display apparatus 110 according to embodiments of the present disclosure, the substrate 111 may be a flexible substrate capable of bending. In the present disclosure, “bending” may have the same meaning as “folding” or “flexible”.

The non-display area NDA is an area where an image is not displayed and may be an area excluding the display area DA. No sub-pixels SP may be disposed in the non-display area NDA. However, at least one dummy sub-pixel that is not directly involved in image display may be disposed in the non-display area NDA.

The non-display area NDA may include a first non-display area NDA1, a bending area BA, and a second non-display area NDA2.

The first non-display area NDA1 may be located around the display area DA and may be the area closest to the display area DA among the first non-display area NDA1, the bending area BA, and the second non-display area NDA2.

The second non-display area NDA2 may include pad areas PA1 and PA2 where various pads are disposed and may be the area farthest from the display area DA among the first non-display area NDA1, the bending area BA, and the second non-display area NDA2.

The bending area BA is an area where the substrate 111 is bent and may be located between the first non-display area NDA1 and the second non-display area NDA2.

The substrate 111 may include the display area DA where an image is displayed and the non-display area NDA surrounding the display area DA. A plurality of sub-pixels SP may be disposed in the display area DA. The non-display area NDA may include a GIP (Gate In Panel) area where a gate driving circuit of a GIP type is formed, a bending area BA through which various wirings pass and where a data driving circuit is electrically connected, and a second non-display area NDA2.

For example, the GIP area may be located at a left and/or right outer area of the display area DA. The non-display area NDA may be located at an upper or lower outer area of the display area DA. The second non-display area NDA2 may be an outer area beyond the bending area BA and may include pad areas PA1 and PA2 where a printed circuit board or other circuit configurations are electrically connected.

As described above, the substrate (SUB) 111 may include the bending area BA, which is bent and folded, and the bending area BA may be located on a lower surface of an unbent portion or the like. The bending area BA may be a part of the non-display area NDA and may be located between the driving circuit area to which the data driving circuit is electrically connected and the display area DA.

In order to drive the sub-pixel SP, a plurality of driving voltage lines DVL for supplying a driving voltage VDD to the plurality of sub-pixels SP and one or more base voltage lines VSSL for applying a base voltage VSS to a common electrode CE of the light-emitting device ED in each sub-pixel SP may further be disposed on the substrate SUB 111.

Referring to FIG. 1, for example, the plurality of driving voltage lines DVL may be arranged in a column direction, but embodiments of the present disclosure are not limited thereto. To efficiently deliver the driving voltage VDD through the plurality of driving voltage lines DVL, a driving voltage pattern integrally formed with or electrically connected to the plurality of driving voltage lines DVL may be disposed in the non-display area NDA.

The plurality of driving voltage lines DVL may be electrically connected to a data driving circuit or a printed circuit board connected to pad areas PA1 and PA2 through the bending area BA by the driving voltage pattern.

The one or more base voltage lines VSSL may be disposed in the non-display area NDA to surround the outer area of the display area DA to efficiently deliver the base voltage VSS. The one or more base voltage lines VSSL may also pass through the bending area BA and be electrically connected to the data driving circuit or the printed circuit board connected to the driving circuit area.

A crack prevention pattern PCD may be formed on the substrate SUB 111. The crack prevention pattern PCD may be formed outside the base voltage line VSSL in the non-display area NDA, but embodiments of the present disclosure are not limited thereto.

For example, the crack prevention pattern PCD may be formed in a zigzag pattern to prevent cracks in the wirings passing through the substrate SUB 111, but embodiments of the present disclosure are not limited thereto.

For example, among the signal lines passing through the bending area BA, some may crack (become electrically open) or short with adjacent signal lines when the bending area BA is bent. In such cases, accurate signals may not be delivered through the cracked (open) or shorted signal lines, causing display driving problems and severely degrading image quality. Accordingly, the crack prevention pattern PCD may be included to prevent such problems, but embodiments of the present disclosure are not limited thereto.

In the aforementioned display apparatus 110, by using a flexible substrate SUB 111 and bending the bending area BA, where the data driving circuit is connected, a portion of the substrate SUB 111 is folded backward. The folded bending area BA is a region where the image cannot be displayed and is not visible from the front. Accordingly, by utilizing the bending structure and wiring arrangement structure as illustrated in FIG. 1, it is possible to significantly reduce the bezel size of the display apparatus 110, thereby achieving a narrow bezel design and providing a design with high aesthetic satisfaction.

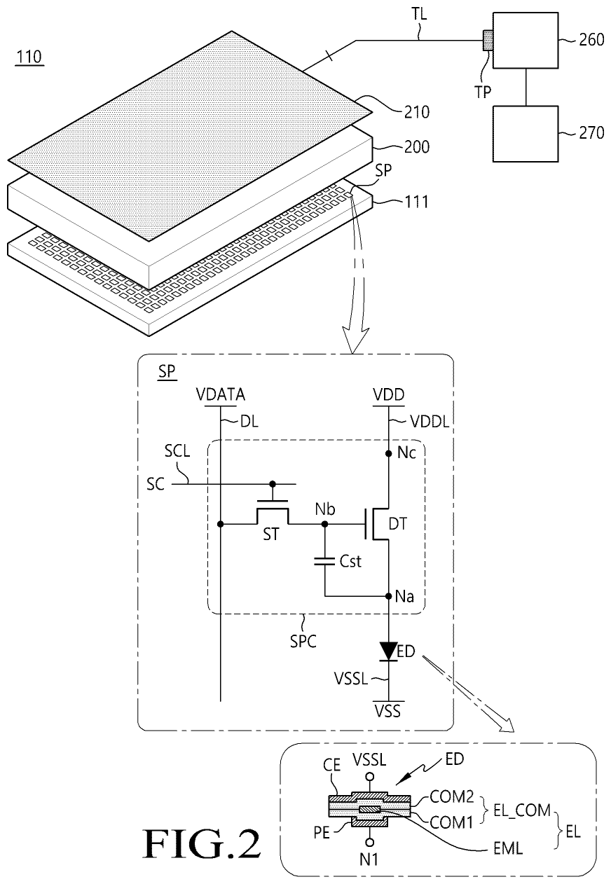

FIG. 2 illustrates the display apparatus 110 according to embodiments of the present disclosure.

Referring to FIG. 2, the display apparatus 110 according to embodiments of the present disclosure may include the substrate 111, a plurality of sub-pixels SP, and the encapsulation layer 200 disposed on the substrate 111. The encapsulation layer 200 may also be referred to as an encapsulation substrate or an encapsulation portion. In an aspect, the plurality of sub-pixels SP may be disposed on the substrate 111.

Referring to FIG. 2, when the display apparatus 110 according to embodiments of the present disclosure is a self-emissive display apparatus, each of the plurality of sub-pixels SP may include a light-emitting device ED and a sub-pixel circuit SPC for driving the light-emitting device ED.

Referring to FIG. 2, the sub-pixel circuit SPC may include a plurality of transistors for driving the light-emitting device ED and at least one capacitor, but embodiments of the present disclosure are not limited thereto. In the present disclosure, the sub-pixel circuit SPC may drive the light-emitting device ED by supplying a driving current to the light-emitting device ED at predetermined timing. The light-emitting device ED may emit light by being driven by the driving current.

The plurality of transistors may include a driving transistor DT for driving the light-emitting device ED and a scan transistor ST that is turned on or off according to a scan signal SC.

The driving transistor DT may supply a driving current to the light-emitting device ED. The scan transistor ST may be configured to control the electrical state of a corresponding node in the sub-pixel circuit SPC or to control the state or operation of the driving transistor DT. The at least one capacitor may include a storage capacitor Cst for maintaining a certain voltage during a frame.

In order to drive the sub-pixel SP, a data signal VDATA, which is an image signal, and a scan signal SC, which is a type of gate signal, may be applied to the sub-pixel SP. In addition, to drive the sub-pixel SP, a common driving signal including a driving voltage VDD and a base voltage VSS may be applied to the sub-pixel SP.

The light-emitting device ED may include a pixel electrode PE, an intermediate layer EL, and a common electrode CE. The intermediate layer EL may be disposed between the pixel electrode PE and the common electrode CE.

For example, the pixel electrode PE may be an electrode disposed in each sub-pixel SP, and the common electrode CE may be an electrode commonly disposed across a plurality of sub-pixels SP. In one example, the pixel electrode PE may be an anode and the common electrode CE may be a cathode. In another example, the pixel electrode PE may be a cathode and the common electrode CE may be an anode. Hereinafter, for convenience of explanation, the pixel electrode PE is described as an anode and the common electrode CE as a cathode.

When the light-emitting device ED is an organic light-emitting device, the intermediate layer EL may include an emitting layer EML, a first common intermediate layer COM1 between the pixel electrode PE and the emitting layer EML, and a second common intermediate layer COM2 between the emitting layer EML and the common electrode CE. The first common intermediate layer COM1 and the second common intermediate layer COM2 may be collectively referred to as a common intermediate layer EL_COM.

The emitting layer EML may be disposed for each sub-pixel SP or commonly disposed across a plurality of sub-pixels SP. The common intermediate layer EL_COM may be commonly disposed across a plurality of sub-pixels SP, but embodiments of the present disclosure are not limited thereto.

That is, the emitting layer EML may be disposed for each emitting area or commonly disposed across a plurality of emitting areas. The common intermediate layer EL_COM may be commonly disposed across a plurality of emitting areas and non-emitting areas, but embodiments of the present disclosure are not limited thereto.

For example, the first common intermediate layer COM1 may include a hole injection layer HIL, an electron blocking layer EBL, and a hole transport layer HTL, but embodiments of the present disclosure are not limited thereto. The second common intermediate layer COM2 may include an electron transport layer ETL, a hole blocking layer HBL, and an electron injection layer EIL, but embodiments of the present disclosure are not limited thereto.

The hole injection layer HIL may inject holes from the pixel electrode PE to the hole transport layer HTL, the hole transport layer HTL may transport holes to the emitting layer EML, the electron injection layer EIL may inject electrons from the common electrode CE to the electron transport layer ETL, and the electron transport layer ETL may transport electrons to the emitting layer EML.

For example, the common electrode CE may be electrically connected to the base voltage line VSSL. A base voltage VSS, which is a type of common voltage, may be applied to the common electrode CE through the base voltage line VSSL. The pixel electrode PE may be electrically connected, either directly or indirectly (through another transistor), to a first node Na of the driving transistor DT in each sub-pixel SP. In the present disclosure, the base voltage VSS may also be referred to as a first common voltage, a low potential power supply voltage, or a low potential voltage, and the base voltage line VSSL may also be referred to as a first common voltage line, a low potential power supply voltage line, or a low potential voltage line.

Each light-emitting device ED may be formed by an overlapping portion of the pixel electrode PE, the emitting layer EML in the intermediate layer EL, and the common electrode CE. A predetermined emitting area may be formed by each light-emitting device ED. For example, the emitting area of each light-emitting device ED may include an overlapping area of the pixel electrode PE, the emitting layer EML in the intermediate layer EL, and the common electrode CE.

For example, the light-emitting device ED may be an organic light-emitting diode (OLED), an inorganic-based light-emitting diode (LED), a quantum dot light-emitting device, a micro LED, or a mini LED, but embodiments of the present disclosure are not limited thereto. For example, when the light-emitting device ED is an organic light-emitting diode (OLED), the intermediate layer EL of the light-emitting device ED may include an organic material-containing intermediate layer.

The driving transistor DT may be a driving transistor for supplying a driving current to the light-emitting device ED. The driving transistor DT may be connected between the driving voltage line VDDL and the light-emitting device ED.

The driving transistor DT may include a first node Na, a second node Nb, and a third node Nc. The first node Na may be electrically connected to the light-emitting device ED, the second node Nb may receive a data signal VDATA, and the third node Nc may receive a driving voltage VDD, which is another type of common voltage, from the driving voltage line VDDL. The driving transistor DT may be connected between the first node Na and the third node Nc. In the present disclosure, the driving voltage VDD may also be referred to as a second common voltage, a high potential power supply voltage, or a high potential voltage, and the driving voltage line VDDL may also be referred to as a second common voltage line, a high potential power supply voltage line, or a high potential voltage line.

In the driving transistor DT, the second node Nb may be a gate node, the first node Na may be a source node or a drain node, and the third node Nc may be a drain node or a source node. Hereinafter, for convenience of explanation, it is assumed that in the driving transistor DT, the second node Nb is a gate node, the first node Na is a source node, and the third node Nc is a drain node, but embodiments of the present disclosure are not limited thereto.

In the example of FIG. 2, a scan transistor ST included in the sub-pixel circuit SPC may be a switching transistor for delivering a data signal VDATA, which is an image signal, to the second node Nb, which is the gate node of the driving transistor DT. The scan transistor ST may be controlled to be turned on or off by a scan signal SC, which is a type of gate signal applied through a scan line SCL, which is a type of gate line GL, and may control the electrical connection between the second node Nb of the driving transistor DT and a data line DL. A drain electrode or source electrode of the scan transistor ST may be electrically connected to the data line DL, a source electrode or drain electrode of the scan transistor ST may be electrically connected to the second node Nb of the driving transistor DT, and a gate electrode of the scan transistor ST may be electrically connected to the scan line SCL.

The storage capacitor Cst may be electrically connected between the first node Na and the second node Nb of the driving transistor DT. The storage capacitor Cst may include at least one capacitor electrode electrically connected to the first node Na of the driving transistor DT or corresponding to the first node Na of the driving transistor DT, and at least one capacitor electrode electrically connected to the second node Nb of the driving transistor DT or corresponding to the second node Nb of the driving transistor DT.

The storage capacitor Cst may be an external capacitor intentionally designed outside the driving transistor DT, rather than an internal capacitor (e.g., parasitic capacitances such as Cgs and Cgd) that may exist between the first node Na and the second node Nb of the driving transistor DT, but embodiments of the present disclosure are not limited thereto.

Each of the driving transistor DT and the scan transistor ST may be an n-type transistor or a p-type transistor, but embodiments of the present disclosure are not limited thereto. For example, one of the driving transistor DT and the scan transistor ST may be either an n-type transistor or a p-type transistor.

The display apparatus 110 may have a top emission structure or a bottom emission structure. When the display apparatus 110 has a top emission structure, at least a portion of the sub-pixel circuit SPC may vertically overlap at least a portion of the light-emitting device ED. Accordingly, the area of the emitting area may be increased and the aperture ratio may be enhanced. When the display apparatus 110 has a bottom emission structure, the sub-pixel circuit SPC may not vertically overlap the light-emitting device ED.

The sub-pixel circuit SPC may have a 2T1C structure including two transistors DT and ST and one capacitor Cst as shown in FIG. 2. In some cases, the sub-pixel circuit SPC may further include one or more transistors and/or one or more capacitors.

In one example, the sub-pixel circuit SPC may have a 3T1C structure including three transistors and one capacitor. In another example, the sub-pixel circuit SPC may have an 8T1C structure including eight transistors and one capacitor. In another example, the sub-pixel circuit SPC may have a 6T2C structure including six transistors and two capacitors. In another example, the sub-pixel circuit SPC may have a 7T1C structure including seven transistors and one capacitor. Embodiments of the present disclosure are not limited thereto. According to the structure of the sub-pixel circuit SPC, the types and the number of gate lines for supplying gate signals to the sub-pixel SP may vary. Also, the types and the number of common driving signals supplied to the sub-pixel SP may vary depending on the structure of the sub-pixel circuit SPC.

Since circuit elements (for example, light-emitting devices ED implemented as organic light-emitting diodes (OLEDs) including organic materials) in each sub-pixel SP are vulnerable to external moisture and oxygen, the encapsulation layer 200 may be disposed in the display apparatus 110. The encapsulation layer 200 may prevent external moisture or oxygen from penetrating into the circuit elements (e.g., the light-emitting device ED). The encapsulation layer 200 may be configured in various forms so that the light-emitting devices ED are not exposed to moisture or oxygen. For example, the encapsulation layer 200 may be composed of two or more layers alternately stacked with an organic film and an inorganic film, but embodiments of the present disclosure are not limited thereto.

Referring to FIG. 2, the display apparatus 110 according to embodiments of the present disclosure may further include a touch sensor layer 210 for providing a touch sensing function, and a touch sensing circuit for sensing a touch sensor formed on the touch sensor layer 210 and determining the presence of a touch or touch coordinates. Here, the touch sensor layer 210 may also be referred to as a touch portion or a touch sensing portion.

For example, the touch sensing circuit may include a touch driving circuit 260 configured to drive and sense a touch sensor formed on the touch sensor layer 210 and generate and output touch sensing data, and a touch controller 270 configured to determine the presence of a touch or touch coordinates based on the touch sensing data provided by the touch driving circuit 260.

The touch sensor layer 210 is a layer where a touch sensor is formed, and the touch sensor may be configured with a plurality of touch electrodes.

In one example, the touch sensor layer 210 may be disposed outside the display apparatus 110 and configured as a separate touch panel different from the display apparatus 110. In this case, the touch panel and the display apparatus 110 may be separately manufactured and combined during the assembly process.

In another example, the touch sensor layer 210 may be embedded in the display apparatus 110. When the touch sensor layer 210 is embedded in the display apparatus 110, the touch sensor layer 210 may be formed on the substrate 111 together with signal lines and electrodes related to display driving during the manufacturing process of the display apparatus 110. For example, the touch sensor layer 210 may be disposed on the encapsulation layer 200. Hereinafter, for convenience of explanation, the case where the touch sensor layer 210 is embedded in the display apparatus 110 is taken as an example.

When the touch sensor layer 210 is embedded in the display apparatus 110, the display apparatus 110 may further include a plurality of touch pads TP to which the touch driving circuit 260 is electrically connected, and a plurality of touch routing lines TL electrically connecting the plurality of touch electrodes and the plurality of touch pads TP, in addition to the plurality of touch electrodes corresponding to the touch sensor. Here, the plurality of touch routing lines TL may also be referred to as a plurality of touch lines. Also, the plurality of touch routing lines TL may correspond to a plurality of touch channels.

The touch driving circuit 260 may supply a touch driving signal to at least one of the plurality of touch electrodes and sense at least one of the plurality of touch electrodes to generate touch sensing data.

The touch sensing circuit may perform touch sensing using a self-capacitance sensing method or a mutual-capacitance sensing method.

When the touch sensing circuit performs touch sensing using a self-capacitance sensing method, it may perform touch sensing based on capacitance between each touch electrode and a touch object (e.g., a finger, a pen, etc.). According to the self-capacitance sensing method, each of the plurality of touch electrodes may serve as both a driving touch electrode and a sensing touch electrode. The touch driving circuit may drive all or part of the plurality of touch electrodes and sense all or part of the plurality of touch electrodes.

When the touch sensing circuit performs touch sensing using a mutual-capacitance sensing method, it may perform touch sensing based on capacitance between two adjacent touch electrodes. According to the mutual-capacitance sensing method, the plurality of touch electrodes may be divided into driving touch electrodes and sensing touch electrodes. The touch driving circuit may drive the driving touch electrodes and sense the sensing touch electrodes. Touch routing lines connected to the driving touch electrodes may be referred to as driving touch routing lines, and touch routing lines connected to the sensing touch electrodes may be referred to as sensing touch routing lines.

The touch driving circuit 260 and the touch controller 270 may be implemented as separate devices or as a single device. In addition, the touch driving circuit 260 and the data driving circuit 120 may be implemented as separate devices or as a single device.

The display apparatus 110 may further include a power supply circuit for supplying various types of power to the display driving circuit and/or the touch sensing circuit. The power supply circuit may supply various voltages and power voltages related to display driving to the display driving circuit or the display apparatus 110.

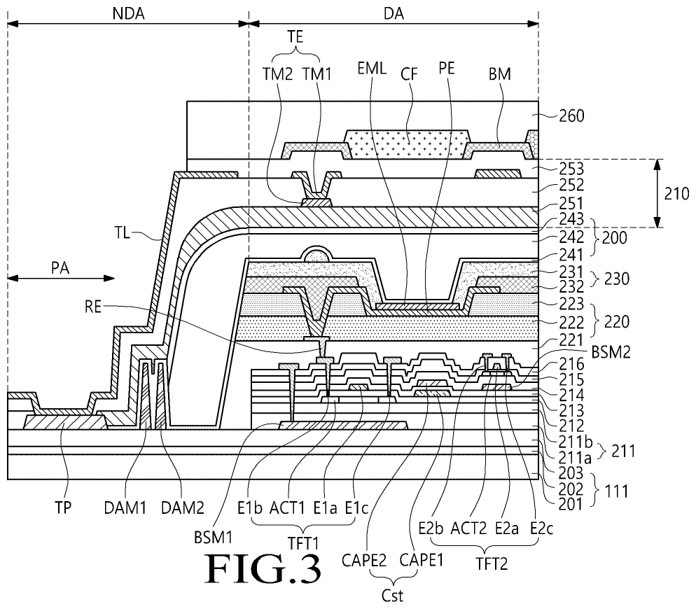

FIG. 3 illustrates an example of a cross-sectional structure of the display apparatus 110 according to embodiments of the present disclosure.

Referring to FIG. 3, the display apparatus 110 according to embodiments of the present disclosure may include the substrate 111, a transistor portion, a light-emitting device portion, and an encapsulation portion, but embodiments of the present disclosure are not limited thereto.

The substrate 111 may be a single layer or a multilayer structure. In the case of a multilayer structure, the substrate 111 may include a first substrate 201, an intermediate substrate layer 202, and a second substrate 203. The intermediate substrate layer 202 may be positioned between the first substrate 201 and the second substrate 203. For example, each of the first substrate 201 and the second substrate 203 may be a polyimide (PI) layer, but embodiments of the present disclosure are not limited thereto. The intermediate substrate layer 202 may be an inorganic insulating layer, but embodiments of the present disclosure are not limited thereto. When a charge is accumulated in the first substrate 201 composed of a polyimide layer, the intermediate substrate layer 202 may block the charge from affecting transistors disposed on the second substrate 203 composed of another polyimide layer.

In addition, the intermediate substrate layer 202 may prevent moisture from penetrating upward through the first substrate 201. For example, the intermediate substrate layer 202 may be formed of a single layer or a plurality of layers of silicon nitride (SiNx) or silicon oxide (SiOx), or a double layer structure of silicon dioxide (SiO2) and silicon nitride (SiNx), but embodiments of the present disclosure are not limited thereto.

The transistor portion may include insulating layers 211, 212, 213, 214, 215, 216, and 220 on the substrate 111, thin film transistors TFT1 and TFT2, a storage capacitor Cst, and various electrodes or signal lines.

The thin film transistors included in the transistor portion may include a first thin film transistor TFT1 and a second thin film transistor TFT2.

The first thin film transistor TFT1 may include a first active layer ACT1, a first electrode E1a, a second electrode E1b, and a third electrode E1c.

The first electrode E1a may be a gate electrode, the second electrode E1b may be a source electrode or a drain electrode, and the third electrode E1c may be a drain electrode or a source electrode. Hereinafter, for convenience of description, the first electrode E1a is referred to as the first gate electrode E1a, the second electrode E1b as the first source electrode E1b, and the third electrode E1c as the first drain electrode E1c. However, embodiments of the present disclosure are not limited thereto.

The first active layer ACT1 may include a first semiconductor material. For example, the first semiconductor material may include an oxide semiconductor, amorphous silicon, polysilicon, or low-temperature polysilicon (LTPS), but embodiments of the present disclosure are not limited thereto. The first thin film transistor TFT1 may be implemented as a p-channel transistor or an n-channel transistor, but embodiments of the present disclosure are not limited thereto.

The second thin film transistor TFT2 may include a second active layer ACT2, a fourth electrode E2a, a fifth electrode E2b, and a sixth electrode E2c.

The fourth electrode E2a may be a gate electrode, the fifth electrode E2b may be a source electrode or a drain electrode, and the sixth electrode E2c may be a drain electrode or a source electrode. Hereinafter, for convenience of description, the fourth electrode E2a is referred to as the second gate electrode E2a, the fifth electrode E2b as the second source electrode E2b, and the sixth electrode E2c as the second drain electrode E2c. However, embodiments of the present disclosure are not limited thereto.

The second active layer ACT2 may include a second semiconductor material. For example, the second semiconductor material may include an oxide semiconductor, amorphous silicon, polysilicon, or low-temperature polysilicon (LTPS), but embodiments of the present disclosure are not limited thereto. The second thin film transistor TFT2 may be implemented as a p-channel transistor or an n-channel transistor, but embodiments of the present disclosure are not limited thereto.

The types of semiconductor materials for the first active layer ACT1 of the first thin film transistor TFT1 and the second active layer ACT2 of the second thin film transistor TFT2 may be as follows.

In one example, the first active layer ACT1 of the first thin film transistor TFT1 and the second active layer ACT2 of the second thin film transistor TFT2 may both include oxide semiconductor materials. In another example, the first active layer ACT1 and the second active layer ACT2 may both include low-temperature polysilicon semiconductor materials. In yet another example, the first active layer ACT1 may include a low-temperature polysilicon semiconductor material and the second active layer ACT2 may include an oxide semiconductor material. In another example, the first active layer ACT1 may include an oxide semiconductor material and the second active layer ACT2 may include a low-temperature polysilicon semiconductor material.

In FIG. 3, the second thin film transistor TFT2 connected to the pixel electrode PE of the light-emitting device ED may be the driving transistor DT according to the configuration of the sub-pixel circuit SPC or another transistor different from the driving transistor DT. For example, in FIG. 3, the second thin film transistor TFT2 connected to the pixel electrode PE of the light-emitting device ED may be a light emission control transistor connected between the driving transistor DT and the light-emitting device ED.

The second active layer ACT2 of the second thin film transistor TFT2 may be positioned higher than the first active layer ACT1 of the first thin film transistor TFT1 from the substrate 111.

A first buffer layer 211 may be disposed under the first active layer ACT1 of the first thin film transistor TFT1, and a second buffer layer 214 may be disposed under the second active layer ACT2 of the second thin film transistor TFT2. For example, the first active layer ACT1 may be located on the first buffer layer 211, and the second active layer ACT2 may be located on the second buffer layer 214. The first buffer layer 211 may be positioned higher than the second buffer layer 214.

The storage capacitor Cst may be disposed in various metal layers within the display apparatus 110. For example, the storage capacitor Cst may include a first capacitor electrode CAPE1 and a second capacitor electrode CAPE2.

The light-emitting device portion may include a plurality of light-emitting devices ED disposed on the planarization layer 220. Each of the plurality of light-emitting devices ED may include a pixel electrode PE and a light-emitting layer EML. Although not shown in FIG. 3, each of the plurality of light-emitting devices ED may further include a common electrode CE.

The encapsulation portion may include the encapsulation layer 200 disposed over the plurality of light-emitting devices ED. The encapsulation layer 200 may be a single layer or a multilayer structure, but embodiments of the present disclosure are not limited thereto. The encapsulation portion may further include at least one dam (DAM) for preventing the encapsulation material from overflowing. Particularly, when a second encapsulation layer 242 included in the encapsulation layer 200 is an organic encapsulation layer made of an organic material, the dam DAM may prevent the organic material from overflowing.

Hereinafter, the structure or vertical structure of the display apparatus 110 according to embodiments of the present disclosure will be described in more detail with reference to FIG. 3.

Referring to FIG. 3, a first buffer layer 211 may be disposed on the substrate 111. The first buffer layer 211 may be a single layer or a multilayer structure, but embodiments of the present disclosure are not limited thereto. In the case of a multilayer structure, the first buffer layer 211 may include a lower buffer layer 211a and an upper buffer layer 211b.

A first active layer ACT1 of the first thin film transistor TFT1 may be disposed on the first buffer layer 211. The first active layer ACT1 may include a channel area in which a channel is formed, a source connection area on one side of the channel area, and a drain connection area on the other side of the channel area.

A first gate insulating layer 212 may be disposed on the first active layer ACT1 of the first thin film transistor TFT1. A first gate electrode E1a of the first thin film transistor TFT1 may be disposed on the first gate insulating layer 212. A first interlayer insulating layer 213 may be disposed on the first gate electrode E1a of the first thin film transistor TFT1. Here, the metal layer in which the first gate electrode E1a is disposed may be referred to as a first gate metal layer.

A second buffer layer 214 may be disposed on the first interlayer insulating layer 213.

A second active layer ACT2 of the second thin film transistor TFT2 may be disposed on the second buffer layer 214. The second active layer ACT2 may include a channel area in which a channel is formed, a source connection area on one side of the channel area, and a drain connection area on the other side of the channel area.

A second gate insulating layer 215 may be disposed on the second active layer ACT2 of the second thin film transistor TFT2. A second gate electrode E2a of the second thin film transistor TFT2 may be disposed thereon. A second interlayer insulating layer 216 may be disposed on the second gate electrode E2a of the second thin film transistor TFT2. Here, the second gate electrode E2a of the second thin film transistor TFT2 may be referred to as a second gate metal layer.

A first source electrode E1b and a first drain electrode E1c of the first thin film transistor TFT1, and a second source electrode E2b and a second drain electrode E2c of the second thin film transistor TFT2 may be disposed on the second interlayer insulating layer 216.

The first source electrode E1b and the first drain electrode E1c of the first thin film transistor TFT1 may be respectively connected to the source connection area and the drain connection area of the first active layer ACT1 through holes formed in the second interlayer insulating layer 216, the second gate insulating layer 215, the second buffer layer 214, the first interlayer insulating layer 213, and the first gate insulating layer 212.

The second source electrode E2b and the second drain electrode E2c of the second thin film transistor TFT2 may be respectively connected to the source connection area and the drain connection area of the second active layer ACT2 through holes formed in the second interlayer insulating layer 216 and the second gate insulating layer 215.

The first source electrode E1b and the first drain electrode E1c of the first thin film transistor TFT1, and the second source electrode E2b and the second drain electrode E2c of the second thin film transistor TFT2 may include a first source-drain metal and may be disposed in a first source-drain metal layer.

Referring to FIG. 3, in one example, the storage capacitor Cst may be formed by a first capacitor electrode CAPE1 and a second capacitor electrode CAPE2. In some cases, the storage capacitor Cst may be formed by three or more capacitor electrodes, and may have a structure in which two or more capacitors are connected in parallel.

Each of the first capacitor electrode CAPE1 and the second capacitor electrode CAPE2 may be disposed in various metal layers in the display apparatus 110.

For example, the first capacitor electrode CAPE1 may include the same first gate metal as the first gate electrode E1a of the first thin film transistor TFT1 disposed on the first gate insulating layer 212, and may be disposed within the first gate metal layer, but embodiments of the present disclosure are not limited thereto. For example, the second capacitor electrode CAPE2 may be disposed on the first interlayer insulating layer 213.

The second source electrode E2b of the second thin film transistor TFT2 may be electrically connected to the second capacitor electrode CAPE2 through holes formed in the second interlayer insulating layer 216, the second gate insulating layer 215, and the second buffer layer 214.

Referring to FIG. 3, the transistor portion may further include a first shield pattern BSM1 disposed on the substrate 111. The first shield pattern BSM1 may overlap the first active layer ACT1 of the first thin film transistor TFT1. The first shield pattern BSM1 may be disposed under the first active layer ACT1 of the first thin film transistor TFT1. For example, the first shield pattern BSM1 may be disposed between the substrate 111 and the first buffer layer 211, or between the lower buffer layer 211a and the upper buffer layer 211b.

The transistor portion may further include a second shield pattern BSM2 disposed on the substrate 111. The second shield pattern BSM2 may overlap the second active layer ACT2 of the second thin film transistor TFT2. The second shield pattern BSM2 may be disposed under the second active layer ACT2 of the second thin film transistor TFT2. For example, the second shield pattern BSM2 may be disposed in a metal layer between the first interlayer insulating layer 313 and the second buffer layer 321. The second shield pattern BSM2 may be disposed in the same metal layer as the second capacitor CAPE2, but embodiments of the present disclosure are not limited thereto. Alternatively, the second shield pattern BSM2 may be disposed in the same first gate metal layer as the first gate electrode E1a of the first thin film transistor TFT1.

A planarization layer 220 may be disposed on the first thin film transistor TFT1 and the second thin film transistor TFT2 and under the light-emitting device ED. The planarization layer 220 may be an organic insulating layer including an organic insulating material.

In one example, the planarization layer 220 may be formed as a single layer. In another example, the planarization layer 220 may include three layers. The planarization layer 220 may include a first planarization layer 221, a second planarization layer 222, and a third planarization layer 223. In another example, the planarization layer 220 may include three or more layers, but embodiments of the present disclosure are not limited thereto.

Referring to FIG. 3, a connection electrode RE may be disposed on the first planarization layer 221. The connection electrode RE may electrically connect the second source electrode E2b of the second thin film transistor TFT2 to the pixel electrode PE.

The connection electrode RE may be electrically connected to the second source electrode E2b of the second thin film transistor TFT2 through a hole in the first planarization layer 221. The second source electrode E2b of the second thin film transistor TFT2 may be electrically connected to the second capacitor electrode CAPE2 of the storage capacitor Cst.

The connection electrode RE may be disposed in the second source-drain metal layer on the first planarization layer 211 and may include a second source-drain metal.

A second planarization layer 222 may be disposed on the connection electrode RE.

A third planarization layer 223 may be disposed on the second planarization layer 222. The third planarization layer 223 may have an opening. The opening of the third planarization layer 223 may correspond to a light-emitting area.

Referring to FIG. 3, the light-emitting device portion may be disposed on the second planarization layer 222 and the third planarization layer 223. The light-emitting device ED may be formed on the second planarization layer 222 and the third planarization layer 223. The light-emitting device ED may include a pixel electrode PE and a light-emitting layer EML. Although not shown in FIG. 3, the light-emitting device ED may further include an intermediate layer EL as shown in FIG. 2. A light-emitting area of the light-emitting device ED may be formed in a region where the pixel electrode PE and the light-emitting layer EML are overlapped and in contact.

The pixel electrode PE may be disposed on the second planarization layer 222 and the third planarization layer 223. The pixel electrode PE may be electrically connected to the connection electrode RE through the opening of the second planarization layer 222 and the third planarization layer 223.

A bank 230 may be disposed on the pixel electrode PE. The bank 230 may include a first bank 231 and a second bank 232. An opening of the bank 230 may expose a portion of the pixel electrode PE to form a light-emitting area. The opening of the bank 230 may overlap a portion of the pixel electrode PE.

For example, the first bank 231 may be formed of an organic material such as benzocyclobutene resin, polyimide resin, acrylic resin, or a photosensitive polymer, but embodiments of the present disclosure are not limited thereto. The second bank 232 may be formed of a material including a black pigment or the like. When the second bank 232 is formed of a material including a black pigment or black dye, it may be a black bank. If the second bank 232 is made of a material containing a black pigment or black dye, external light or reflected external light may be blocked, thereby improving the luminance of the display apparatus 110.

The light-emitting layer EML of the light-emitting device ED may be disposed on the pixel electrode PE.

Referring to FIG. 3, the encapsulation portion may be disposed on the light-emitting device portion and may be positioned on the bank 230. The encapsulation portion may include the encapsulation layer 200 formed on the bank 230.

The encapsulation layer 200 may prevent moisture or oxygen from penetrating into the light-emitting device ED. For example, the encapsulation layer 200 may prevent moisture or oxygen from penetrating into the organic material included in the intermediate layer EL of the light-emitting device ED. The encapsulation layer 200 may be configured as a single layer or a multilayer structure, but embodiments of the present disclosure are not limited thereto.

In one example, the encapsulation layer 200 may include a first encapsulation layer 241, a second encapsulation layer 242, and a third encapsulation layer 243, but embodiments of the present disclosure are not limited thereto. For example, the first encapsulation layer 241 and the third encapsulation layer 243 may include inorganic encapsulation layers, and the second encapsulation layer 242 may include an organic encapsulation layer, but embodiments of the present disclosure are not limited thereto.

The display apparatus 110 according to embodiments of the present disclosure may further include an embedded touch sensor. In this case, the display apparatus 110 may include the touch sensor layer 210 disposed on the encapsulation layer 200 in which the touch sensor is formed.

Referring to FIG. 3, the touch sensor layer 210 may include a plurality of touch electrodes TE corresponding to a touch sensor and at least one touch metal layer for forming the plurality of touch electrodes TE.

For example, to form the plurality of touch electrodes TE, the touch sensor layer 210 may include a first touch metal layer in which a plurality of first touch metals TM1 are disposed and a second touch metal layer in which a plurality of second touch metals TM2 are disposed. In this case, the touch sensor layer 210 may further include a touch interlayer insulating layer 252 disposed between the first touch metal layer and the second touch metal layer.

For example, one of the first touch metal layer and the second touch metal layer may be a sensor metal layer, and the other may be a bridge metal layer.

In one example, the first touch metal layer may be the bridge metal layer and the second touch metal layer may be the sensor metal layer. In this case, the plurality of second touch metals TM2 disposed in the second touch metal layer may be sensor metals forming the touch sensor, and the plurality of first touch metals TM1 disposed in the first touch metal layer may be bridge metals electrically connecting the sensor metals, i.e., the second touch metals TM2. For example, two or more second touch metals TM2 and at least one first touch metal TM1 may form one first touch electrode TE1. In this case, two or more second touch electrodes TE2 may be electrically connected through at least one first touch metal TM1.

In another example, the first touch metal layer may be the sensor metal layer, and the second touch metal layer may be the bridge metal layer. In this case, the plurality of first touch metals TM1 disposed in the first touch metal layer may be sensor metals forming the touch sensor, and the plurality of second touch metals TM2 disposed in the second touch metal layer may be bridge metals electrically connecting the sensor metals, i.e., the first touch metals TM1.

In another example, the first touch metal layer and the second touch metal layer may respectively be a sensor metal layers and a bridge metal layer. For example, the first touch metal layer may include both sensor metal and bridge metal, and the second touch metal layer may also include both sensor metal and bridge metal. In this case, a plurality of first touch metals TM1 arranged within the first touch metal layer may include sensor metals and bridge metals, and a plurality of second touch metals TM2 arranged within the second touch metal layer may also include sensor metals and bridge metals.

Referring to FIG. 3, the touch sensor layer 210 may further include a touch buffer layer 251 disposed on the encapsulation layer 200. The touch buffer layer 251 may be disposed between the encapsulation layer 200 and the touch metal layer. For example, the first touch metal layer may be disposed on the touch buffer layer 251, and the touch interlayer insulating layer 252 may be disposed on the first touch metal layer.

Referring to FIG. 3, the touch sensor layer 210 may further include a touch protection layer 253 disposed covering the touch metal layer. For example, the touch protection layer 253 may be disposed on the second touch metal layer.

For example, the touch buffer layer 251 may be an inorganic layer including an inorganic insulating material or an organic layer including an organic insulating material, the touch interlayer insulating layer 252 may be an inorganic layer including an inorganic insulating material or an organic layer including an organic insulating material, and the touch protection layer 253 may be an inorganic layer including an inorganic insulating material or an organic layer including an organic insulating material.

For example, at least one of the touch buffer layer 251 and the touch interlayer insulating layer 252 may be extended from the display area DA to the non-display area NDA. The touch protection layer 253 may be extended from the display area DA to the non-display area NDA.

The touch routing line TL may electrically connect the touch electrodes TE and the touch pads TP. The touch routing line TL may be configured with at least one of the first touch metal TM1 and the second touch metal TM2.

For example, one touch routing line TL may include a plurality of wiring sections, and each of the plurality of wiring sections may be a single wiring section or a double wiring section. Here, the single wiring section may be a wiring section having one signal path, and the double wiring section may be a wiring section in which two signal paths are connected in parallel.

The touch routing line TL may be disposed along the inclined surface of the encapsulation layer 200 and may extend to the touch pad TP over the dams DAM1 and DAM2.

The touch buffer layer 251 may have an opening exposing at least a portion of the touch pad TP. The touch routing line TL may be electrically connected to the touch pad TP through the opening of the touch buffer layer 251. The touch interlayer insulating layer 252 may be disposed on the touch buffer layer 251 and may be extended to the area where the touch pad TP is disposed. The touch protection layer 253 may be disposed only in the display area DA or may be extended to the non-display area NDA to cover the touch routing line TL. In some cases, the touch protection layer 253 may be further extended over the touch pad TP.

Each of the plurality of touch electrodes TE may be a mesh-type electrode having a plurality of openings. In this case, each of the plurality of touch electrodes TE may be configured with at least one of the second touch metals TM2. However, embodiments of the present disclosure are not limited thereto.

For example, the plurality of touch electrodes TE may include a first touch electrode TE1 and a second touch electrode TE2. When the first touch metal layer is a bridge metal layer and the second touch metal layer is a sensor metal layer, two or more second touch metals TM2 forming the first touch electrode TE1 corresponding to the touch sensor may be electrically connected through at least one first touch metal TM1 serving as a bridge metal. For example, two spaced second touch metals TM2 may be electrically connected by a first touch metal TM1 to form one first touch electrode TE1.

Referring to FIG. 3, the plurality of first touch metals TM1 and the plurality of second touch metals TM2 may be disposed so as not to overlap the light-emitting device ED. The plurality of first touch metals TM1 and the plurality of second touch metals TM2 may overlap the bank 200. Accordingly, the light-emitting efficiency of the light-emitting device ED may be improved.

Referring to FIG. 3, the touch routing line TL may connect the touch pad TP disposed in the pad area PA in the non-display area NDA and the touch electrode TE disposed in the display area DA. To this end, the touch routing line TL may be disposed across the non-display area NDA.

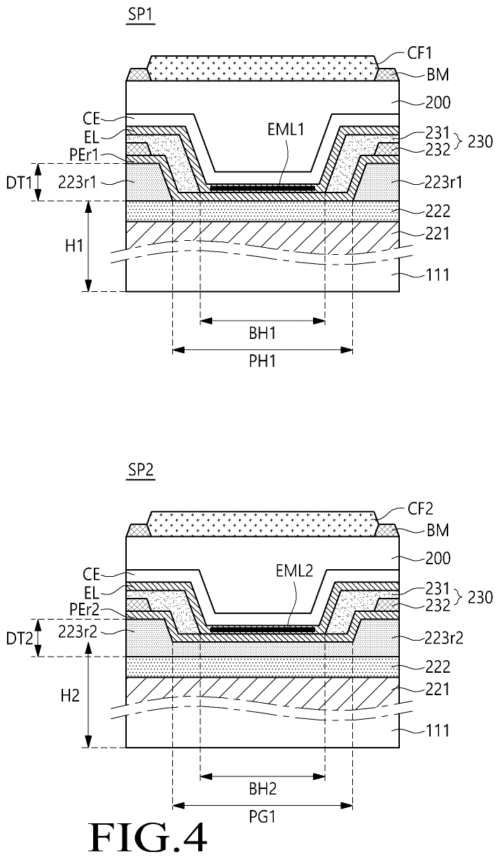

FIG. 4 illustrates a cross-sectional view of a first sub-pixel SP1 and a second sub-pixel SP2 of the display apparatus 110 according to embodiments of the present disclosure. In one or more aspects, a sub-pixel may be sometimes referred to as a sub-pixel area, and vice versa. For instance, a first sub-pixel may be sometimes referred to as a first sub-pixel area, and vice versa. For instance, a second sub-pixel may be sometimes referred to as a second sub-pixel area, and vice versa.

A first planarization layer 221 may be disposed on the substrate 111. In FIG. 4, while the first thin-film transistor TFT1 and the second thin-film transistor TFT2 are included in the display apparatus 110, the first thin-film transistor TFT1 and the second thin-film transistor TFT2 may be omitted from depiction between the substrate 111 and the first planarization layer 221, simply for brevity.

A second planarization layer 222 may be disposed on the first planarization layer 221.

In the first sub-pixel area SP1, a first insulating layer 223r1 having a first opening PH1 may be disposed on the second planarization layer 222. A first pixel electrode PEr1 may be disposed on the second planarization layer 222 at the first opening PH1 and extend along an inner side surface of the first opening PH1 of the first insulating layer 223r1 (or extend along an inner side surface of the first insulating layer 223r1).

In the second sub-pixel area SP2, a second insulating layer 223r2 having a first groove PG1 may be disposed on the second planarization layer 222. A second pixel electrode PEr2 may be disposed on the second insulating layer 223r2 at the first groove PG1 and extend along an inner side surface of the first groove PG1 of the second insulating layer 223r2 (or extend along an inner side surface of the second insulating layer 223r2).

A width of the first opening PH1 of the first sub-pixel SP1 may be equal to a width of the first groove PG1 of the second sub-pixel SP2. The first groove PG1 may have a depth DT2 smaller than a depth DT1 of the first opening PH1. The depth DT1 of the first opening PH1 may correspond to a distance between a top surface of the first insulating layer 223r1 (surrounding the first opening PH1) and a top location of a first height H1. The depth DT2 of the first groove PG1 may correspond to a distance between a top surface of the second insulating layer 223r2 (surrounding the first groove PG1) and a top location of a second height H2. The top location of the first height H1 may correspond to, or may be, a bottom surface of the first insulating layer 223r1. The top location of the second height H2 may correspond to, or may be, a bottom surface of the second insulating layer 223r2.

In a plan view, the size of the area occupied by the first groove PG1 may be identical to the size of the area occupied by the first opening PH1.

A second bank 232 may be disposed between the common electrode CE and the first pixel electrode PEr1 and between the common electrode CE and the second pixel electrode PEr2, and located outside the first opening PH1 and the first groove PG1.

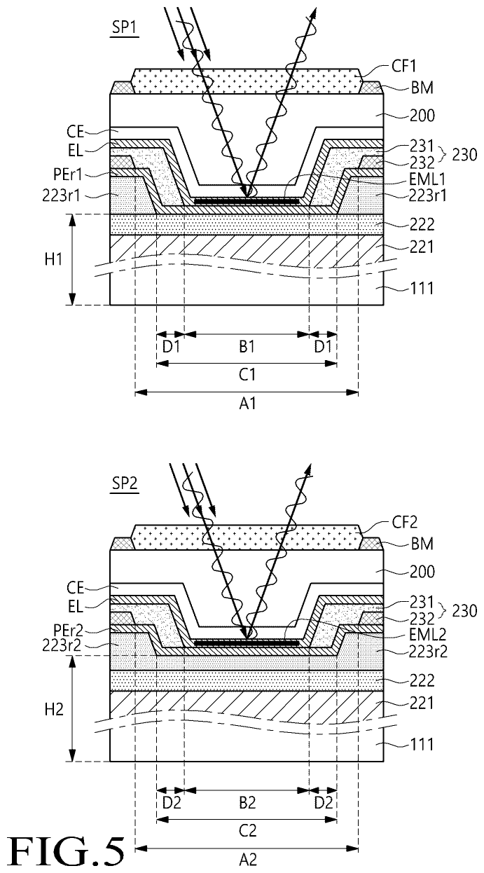

A first distance D1 (see, e.g., FIG. 5) between an end of an inclined surface of the first bank 231 and an end of an inclined surface of the first insulating layer 223r1 in the first sub-pixel SP1 may be equal to a second distance D2 (see, e.g., FIG. 5) between an end of an inclined surface of the first bank 231 and an end of an inclined surface of the second insulating layer 223r2 in the second sub-pixel SP2.

The second hole BH2 may have an area identical to an area of the first hole BH1.

The first hole BH1 and the second hole BH2 may have the same width.

A first intermediate layer and a second intermediate layer may be disposed on the first pixel electrode PEr1 and the second pixel electrode PEr2, respectively, and may extend along inner side surfaces of the first bank 231 up to a top surface of the first bank 231. The first intermediate layer may include a first light-emitting layer EML1, and the second intermediate layer may include a second light-emitting layer EML2.

For instance, a first intermediate layer (see, e.g., EL of SP1) may be disposed on the first pixel electrode PEr1. The first intermediate layer may be disposed at the first hole BH1 and extend along an inner side surface of the first hole BH1 (or the first bank 231) up to a top surface of the first bank 231. The first intermediate layer may include a first light-emitting layer EML1.

For instance, a second intermediate layer (see, e.g., EL of SP2) may be disposed on the second pixel electrode PEr2. The second intermediate layer may be disposed at the second hole BH2 and extend along an inner side surface of the second hole BH2 (or the first bank 231) up to a top surface of the first bank 231. The second intermediate layer may include a second light-emitting layer EML2.

A common electrode CE may be disposed on the first intermediate layer and the second intermediate layer.

The encapsulation layer 200 may be disposed on the common electrode CE. A first color filter CF1 overlapping the first pixel electrode PEr1 may be disposed on the encapsulation layer 200. A second color filter CF2 overlapping the second pixel electrode PEr2 may be disposed on the encapsulation layer 200.

The first pixel electrode PEr1 may have a first inclined portion extending along an inner side surface of the first insulating layer 223r1, and the second pixel electrode PEr2 may have a second inclined portion extending along an inner side surface of the second insulating layer 223r2.

The first color filter CF1 may overlap the first inclined portion, and the second color filter CF2 may overlap the second inclined portion.

Black matrices BM may be disposed at opposite ends of the first color filter CF1 and the second color filter CF2. The black matrices BM may be disposed to overlap the first bank 231.

A shortest distance between a bottom surface of the substrate 111 and the first pixel electrode PEr1 may correspond to a first height H1. A shortest distance between a bottom surface of the substrate 111 and the second pixel electrode PEr2 may correspond to a second height H2. The second height H2 of the second sub-pixel SP2 may be greater than the first height H1 of the first sub-pixel SP1.

FIG. 5 illustrates a cross-sectional view of the first sub-pixel SP1 and the second sub-pixel SP2 of the display apparatus 110 according to embodiments of the present disclosure.

Descriptions of substantially the same contents as explained in FIG. 4 may be omitted. The descriptions provided for elements in one or more figures (e.g., FIGS. 1-4) may apply to elements in other figures (e.g., FIG. 5) that use the same reference numerals unless stated otherwise.

In the area of the first sub-pixel SP1, a distance between ends of inclined surfaces of the second bank 232 is referred to as A1.

In the area of the second sub-pixel SP2, a distance between ends of inclined surfaces of the second bank 232 is referred to as A2.

In the area of the first sub-pixel SP1, a distance between ends of inclined surfaces of the first bank 231 is referred to as B1.

In the area of the second sub-pixel SP2, a distance between ends of inclined surfaces of the first bank 231 is referred to as B2.

In the area of the first sub-pixel SP1, a distance between ends of inclined surfaces of the first insulating layer 223r1 is referred to as C1.

In the area of the second sub-pixel SP2, a distance between ends of inclined surfaces of the second insulating layer 223r2 is referred to as C2.

In the area of the first sub-pixel SP1, a distance between an end of an inclined surface of the first insulating layer 223r1 and an end of an inclined surface of the first bank 231 is referred to as D1. The distance D1 may correspond to a first separation distance and may correspond to a difference between the distances C1 and B1.

In the area of the second sub-pixel SP2, a distance between an end of an inclined surface of the second insulating layer 223r2 and an end of an inclined surface of the first bank 231 is referred to as D2. The distance D2 may correspond to a second separation distance and may correspond to a difference between the distances C2 and B2.

Referring to FIG. 5, the respective lengths of A1, B1, C1, and D1 in the first sub-pixel SP1 may be identical to the respective lengths of A2, B2, C2, and D2 in the second sub-pixel SP2.

In the display apparatus 110 where sub-pixels arranged have identical first height H1 and second height H2, a problem may arise in that some light undergoes destructive interference and other light undergoes constructive interference, causing an annular mura phenomenon.

To prevent annular mura phenomena, the display apparatus 110 according to an embodiment of the present disclosure may have a structure in which externally incident light reflected from an area of the first sub-pixel SP1 and externally incident light reflected from an area of the second sub-pixel SP2 undergo destructive interference.

In order for externally incident light reflected from the area of the first sub-pixel SP1 and externally incident light reflected from the area of the second sub-pixel SP2 to undergo destructive interference, a path difference between the two reflected lights may be an odd multiple of λ/2 (hereinafter, for convenience of description, λ/2 is used as an example). In an aspect, λ may represent a wavelength of one the two reflected lights.

To ensure that the externally incident light reflected from the area of the first sub-pixel SP1 and the externally incident light reflected from the area of the second sub-pixel SP2 have a path difference of λ/2, twice the difference between a first height H1 and a second height H2 may be equal to λ/2. In other words, the difference between the first height H1 and the second height H2 may be λ/4.

The difference between the first height H1 and the second height H2 may correspond to a thickness of the second insulating layer 223r2 having the first groove PG1 in the area of the second sub-pixel SP2. In this case, a step difference of the third planarization layer 223 between the first sub-pixel SP1 and the second sub-pixel SP2 may correspond to the thickness of the second insulating layer 223r2 having the first groove PG1 in the second sub-pixel SP2.

When the thickness of the second insulating layer 223r2 having the first groove PG1 in the area of the second sub-pixel SP2 (i.e., the difference between the first height H1 and the second height H2) is λ/4, externally incident light reflected from the area of the first sub-pixel SP1 and externally incident light reflected from the area of the second sub-pixel SP2 may undergo destructive interference, thereby preventing the occurrence of annular mura. As a result, the reflectance visibility of the display apparatus 110 may be improved. Hereinafter, the structure of the display apparatus 110 regarding this will be described in more detail.

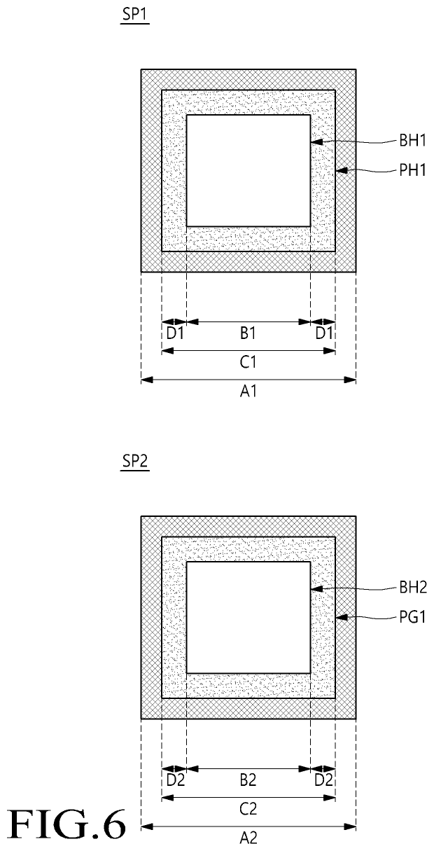

FIG. 6 illustrates a plan view of the display apparatus 110 according to embodiments of the present disclosure.

Referring to FIG. 6, the area of the first sub-pixel SP1 may include A1, B1, C1, and D1.

A1 may correspond to a width of a hole of the second bank 232.

B1 may correspond to a width of the first hole BH1 of the first bank 231.

C1 may correspond to a width of the first opening PH1 of the first insulating layer 223r1.

D1 may correspond to a difference between C1 and B1.

D1 may correspond to a second separation distance between an end of an inclined surface of the first insulating layer 223r1 and an end of an inclined surface of the first bank 231.

Referring to FIG. 6, the area of the second sub-pixel SP2 may include A2, B2, C2, and D2.

A2 may correspond to a width of a hole of the second bank 232.

B2 may correspond to a width of the second hole BH2 of the first bank 231.

C2 may correspond to a width of the first groove PG1 of the second insulating layer 223r2.

D2 may correspond to a difference between C2 and B2. D2 may correspond to a second separation distance between an end of an inclined surface of the second insulating layer 223r2 and an end of an inclined surface of the first bank 231.

The respective widths of A1, B1, C1, and D1 of the first sub-pixel SP1 may be identical to the respective widths of A2, B2, C2, and D2 of the second sub-pixel SP2.

An area occupied by the first opening PH1 may be identical to an area occupied by the first groove PG1.

The first hole BH1 may have an area identical to an area of the second hole BH2.

The dimensions A1, B1, C1, D1, A2, B2, C2, and D2 shown in FIG. 6 may correspond to, or may be the same as, the dimensions A1, B1, C1, D1, A2, B2, C2, and D2 shown in FIG. 5, respectively.

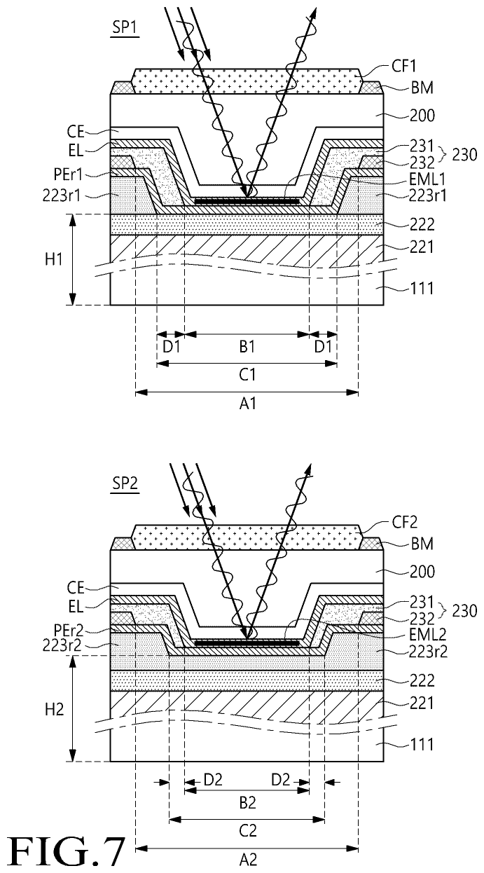

FIG. 7 illustrates a cross-sectional view of a first sub-pixel and a second sub-pixel of the display apparatus 110 according to embodiments of the present disclosure.

Detailed descriptions of elements substantially identical to those described with reference to FIG. 4 and FIG. 5 may be omitted for brevity. The descriptions provided for elements in one or more figures (e.g., FIGS. 1-6) may apply to elements in other figures (e.g., FIG. 7) that use the same reference numerals unless stated otherwise.

Referring to FIG. 7, the respective lengths of A1 and B1 of the first sub-pixel SP1 may be identical to the respective lengths of A2 and B2 of the second sub-pixel SP2. C2 and D2 of the second sub-pixel SP2 may have lengths smaller than the lengths of C1 and D1 of the first sub-pixel SP1, respectively.

A second height H2 of the second sub-pixel SP2 shown in FIG. 7 may be formed to have the same height as the second height H2 shown in FIG. 5.

A first groove PG1 of the second sub-pixel SP2 shown in FIG. 7 may have a smaller width than a first opening PH1 of the first sub-pixel SP1 shown in FIG. 7. Thus, C2, which corresponds to a width of the first groove PG1 of the second sub-pixel SP2 shown in FIG. 7, may be less than C1, which corresponds to a width of the first opening PH1 of the first sub-pixel SP1 shown in FIG. 7.

As a second height H2 greater than a first height H1 is formed in the second sub-pixel SP2, an OLED side mirror (OSM) effect may be reduced. Accordingly, the reduced OSM effect may be compensated by forming a second separation distance D2 smaller than a first separation distance D1.

In the display apparatus 110 in which sub-pixels having the same first height H1 and second height H2 are arranged, light may undergo both destructive and constructive interference, causing a problem of annular mura.

To prevent annular mura, the display apparatus 110 according to an embodiment of the present disclosure may have a structure in which externally incident light reflected from areas of the first sub-pixel SP1 and the second sub-pixel SP2 undergo destructive interference.

For externally incident light reflected from the area of the first sub-pixel SP1 and externally incident light reflected from the area of the second sub-pixel SP2 to undergo destructive interference, a path difference between the two reflected lights may be an odd multiple of λ/2 (hereinafter, λ/2 is used for ease of explanation).

In order for the reflected lights to have a path difference of λ/2, a value obtained by doubling the difference between the first height H1 and the second height H2 may become λ/2. That is, the difference between the first height H1 and the second height H2 may be λ/4.

The difference between the first height H1 and the second height H2 may correspond to a thickness of the second insulating layer 223r2 having the first groove PG1 in the area of the second sub-pixel SP2. Here, the step difference in the third planarization layer 223 between the first sub-pixel SP1 and the second sub-pixel SP2 may correspond to the thickness of the second insulating layer 223r2 having the first groove PG1.

When the thickness of the second insulating layer 223r2 having the first groove PG1 (i.e., the difference between the first height H1 and the second height H2) is λ/4, the externally incident lights reflected from the areas of the first sub-pixel SP1 and the second sub-pixel SP2 may undergo destructive interference, thus preventing annular mura. As a result, reflectance visibility of the display apparatus 110 may be improved.

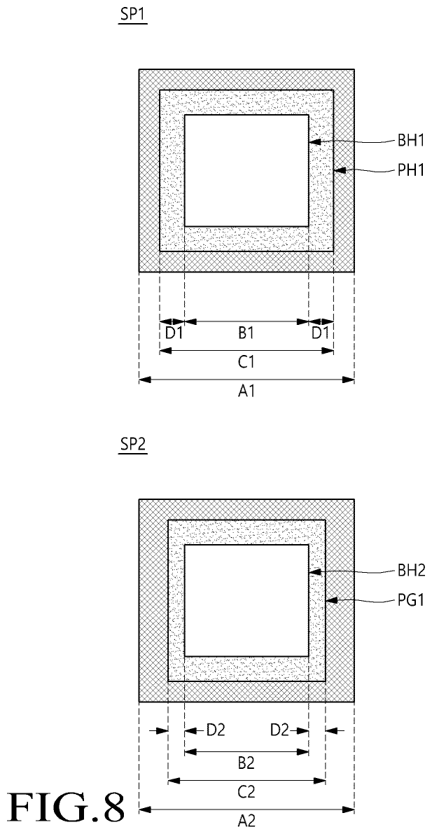

FIG. 8 illustrates a plan view of the display apparatus 110 according to embodiments of the present disclosure.

A1 may correspond to a hole of the second bank 232.

A2 may correspond to a hole of the second bank 232.

B1 may correspond to the first hole BH1 of the first bank 231.

B2 may correspond to the second hole BH2 of the first bank 231.

C1 may correspond to the first opening PH1 of the first insulating layer 223r1.

C2 may correspond to the first groove PG1 of the second insulating layer 223r2.

D1 may correspond to a difference between B1 and C1. D1 may correspond to a first separation distance between an end of an inclined surface of the first insulating layer 223r1 and an end of an inclined surface of the first bank 231.

D2 may correspond to a difference between B2 and C2. D2 may correspond to a second separation distance between an end of an inclined surface of the second insulating layer 223r2 and an end of an inclined surface of the first bank 231.

An area occupied by the first groove PG1 may not be identical to an area occupied by the first opening PH1. The area occupied by the first groove PG1 may be smaller than the area occupied by the first opening PH1.

A width of the first groove PG1 (e.g., C2) may be smaller than a width of the first opening PH1 (e.g., C1).

The second hole BH2 may have an area identical to an area of the first hole BH1.

A width of the second hole BH2 may be identical to a width of the first hole BH1.

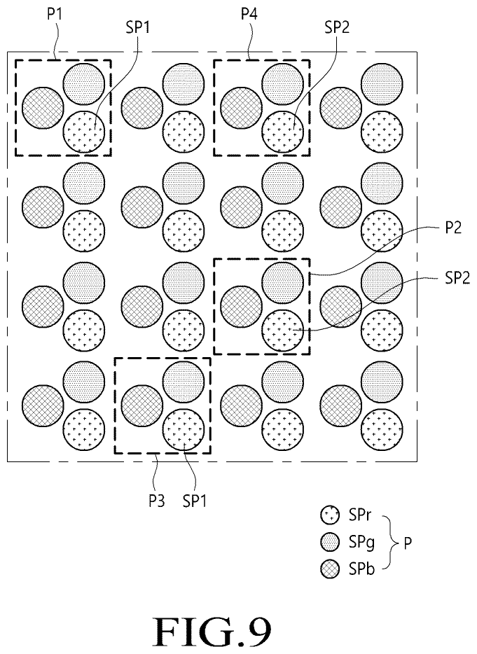

FIG. 9 illustrates a pixel arrangement of the display apparatus 110 according to embodiments of the present disclosure.

One pixel (or each pixel) may include a red sub-pixel, a green sub-pixel, and a blue sub-pixel. The display apparatus 110 according to embodiments of the present disclosure may further include first to fourth pixels (or a plurality of first to fourth pixels), and the first sub-pixel SP1 may be included in each of the first pixel P1 and the third pixel P3 (or in each of the first pixels P1 and each of the third pixels P3), while the second sub-pixel SP2 may be included in each of the second pixel P2 and the fourth pixel P4 (or in each of the second pixels P2 and each of the fourth pixels P4).

A distance between the first pixel P1 and the third pixel P3 may be different from a distance between the second pixel P2 and the fourth pixel P4.

The first pixel P1 and the third pixel P3 may be adjacent to or not adjacent to the second pixel P2 and the fourth pixel P4.

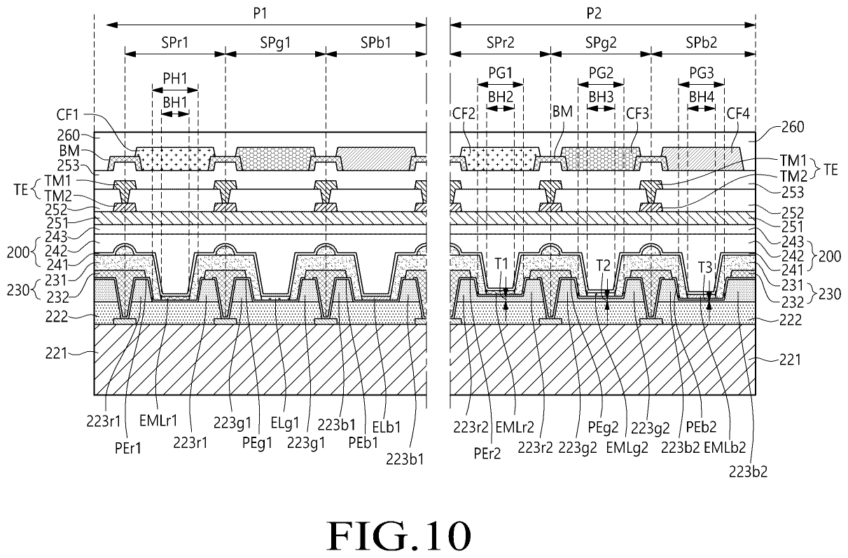

FIG. 10 illustrates a cross-sectional view of the first pixel P1 and the second pixel P2 of the display apparatus 110 according to embodiments of the present disclosure. The descriptions provided for elements in one or more figures (e.g., FIGS. 1-6) may apply to elements in other figures (e.g., FIG. 10) that use the same reference numerals unless stated otherwise.

Referring to FIG. 10, the first pixel P1 may include a first red sub-pixel SPr1, a first green sub-pixel SPg1, and a first blue sub-pixel SPb1. The second pixel P2 may include a second red sub-pixel SPr2, a second green sub-pixel SPg2, and a second blue sub-pixel SPb2.

Hereinafter, the first red sub-pixel SPr1 of the first pixel P1 may be referred to as the first sub-pixel SP1, and the second red sub-pixel SPr2, the second green sub-pixel SPg2, and the second blue sub-pixel SPb2 of the second pixel P2 may be referred to as the second sub-pixel SP2, the third sub-pixel SP3, and the fourth sub-pixel SP4, respectively.

The display apparatus 110 according to embodiments of the present disclosure may include the substrate 111. A first planarization layer 221 may be disposed on the substrate 111. A second planarization layer 222 may be disposed on the first planarization layer 221.

A first insulating layer 223r1 may be disposed on the second planarization layer 222, located in an area of the first sub-pixel SP1, and may have a first opening PH1. A second insulating layer 223r2 may be disposed on the second planarization layer 222, located in an area of the second sub-pixel SP2, and may have a first groove PG1.

A width of the first opening PH1 of the first sub-pixel SP1 may be identical to a width of the first groove PG1 of the second sub-pixel SP2.

A distance D1 between an end of an inclined surface of the first insulating layer 223r1 and an end of an inclined surface of the first bank 231 may be identical to a distance D2 between an end of an inclined surface of the second insulating layer 223r2 and an end of an inclined surface of the first bank 231.

The first groove PG1 may have a depth smaller than a depth of the first opening PH1.

A first pixel electrode PEr1 may be disposed in the area of the first sub-pixel SP1, located on the second planarization layer 222 at the first opening PH1, and may extend along an inner side surface of the first insulating layer 223r1. A second pixel electrode PEr2 may be disposed in the area of the second sub-pixel SP2, located on a bottom surface of the first groove PG1, and may extend along an inner side surface of the first groove PG1.

A second bank 232 may be disposed on the first pixel electrode PEr1 and the second pixel electrode PEr2, and may be located outside the first opening PH1 and the first groove PG1.

A first bank 231 may be disposed on the first pixel electrode PEr1 and the second pixel electrode PEr2, and may have a first hole BH1 overlapping the first opening PH1 and smaller than the first opening PH1, and a second hole BH2 overlapping the first groove PG1 and smaller than the first groove PG1.

The second hole BH2 may have an area identical to an area of the first hole BH1.

A first light-emitting layer EMLr1 may be disposed on the first pixel electrode PEr1. A second light-emitting layer EMLr2 may be disposed on the second pixel electrode PEr2.

Although not illustrated in FIG. 10, a common electrode CE may be disposed on the first light-emitting layer EMLr1 and the second light-emitting layer EMLr2, and may extend along inner side surfaces of the first hole BH1 and the second hole BH2 of the first bank 231 up to a top surface of the first bank 231 (or extend along inner side surfaces of the first bank 231 up to a top surface of the first bank 231.

The display apparatus 110 according to embodiments of the present disclosure may further include the encapsulation layer 200 disposed on the first bank 231 and the common electrode CE, the first color filter CF1 disposed on the encapsulation layer 200 and overlapping the first pixel electrode PEr1, and a second color filter CF2 disposed on the encapsulation layer 200 and overlapping the second pixel electrode PEr2.

The first pixel electrode PEr1 may have a first inclined portion extending along an inner side surface of the first insulating layer 223r1, and the second pixel electrode PEr2 may have a second inclined portion extending along an inner side surface of the second insulating layer 223r2.

The first color filter CF1 may overlap the first inclined portion, and the second color filter CF2 may overlap the second inclined portion.

A first separation distance D1 between an end of an inclined surface of the first bank 231 and an end of an inclined surface of the first insulating layer 223r1 in the first sub-pixel SP1 may be identical to a second separation distance D2 between an end of an inclined surface of the first bank 231 and an end of an inclined surface of the second insulating layer 223r2 in the second sub-pixel SP2.

The first sub-pixel SP1 and the second sub-pixel SP2 may emit light of the same color, and the first color filter CF1 may have a thickness identical to that of the second color filter CF2.

In an area of a third sub-pixel SP3 of the display apparatus 110 according to embodiments of the present disclosure, a third insulating layer 223g2 having a second groove PG2 may be disposed on the second planarization layer 222. A third pixel electrode PEg2 may be disposed in the area of the third sub-pixel SP3, located on the third insulating layer 223g2 at the second groove PG2 (or located at a bottom surface of the second groove PG2), and may extend along an inner side surface of the third insulating layer 223g2.

The second bank 232 may be disposed on the third pixel electrode PEg2 and located outside the second groove PG2.

The first bank 231 may be disposed on the third pixel electrode PEg2, and may have a third hole BH3 overlapping the second groove PG2, where the third hole BH3 may be smaller than the second groove PG2.

A third light-emitting layer EMLg2 may be disposed on the third pixel electrode PEg2.

Although not illustrated in FIG. 10, the common electrode CE may be disposed on the third light-emitting layer EMLg2 and may extend along an inner side surface of the third hole BH3 of the first bank 231 up to a top surface of the first bank 231 (or extend along an inner side surface of the first bank 231 up to a top surface of the first bank 231).

The display apparatus 110 according to embodiments of the present disclosure may further include the encapsulation layer 200 disposed on the first bank 231 and the common electrode CE, and a third color filter CF3 disposed on the encapsulation layer 200 and overlapping the third pixel electrode PEg2.

The third pixel electrode PEg2 may have a third inclined portion extending along an inner side surface of the third insulating layer 223g2.

The third color filter CF3 may overlap the third inclined portion.

A distance between a bottom surface of the first groove PG1 and a rear surface of the second insulating layer 223r2 may have a first thickness T1, and a distance between a bottom surface of the second groove PG2 and a rear surface of the third insulating layer 223g2 may have a second thickness T2 different from the first thickness T1. The rear surface of the second insulating layer 223r2 and the rear surface of the third insulating layer 223g2 may face the first planarization layer 221 and/or the substrate 111.

The thickness (e.g., T1, T2, and T3) may vary according to a wavelength of light emitted from each sub-pixel. The thickness and the wavelength may be proportional to each other. As the wavelength increases, the thickness may also increase. The wavelength of red light may be longer than that of green and blue light, and the wavelength of green light may be longer than that of blue light.

The second sub-pixel SP2 may emit red light, the third sub-pixel SP3 may emit green light, and the first thickness T1 may be greater than the second thickness T2.

The display apparatus 110 according to embodiments of the present disclosure may include a fourth insulating layer 223b2 disposed on the second planarization layer 222 in an area of a fourth sub-pixel SP 4. The fourth insulating layer 223b2 may have a third groove PG3. A fourth pixel electrode PEb2 may be disposed in the area of the fourth sub-pixel SP4, located on the fourth insulating layer 223b2 at the third groove PG3, and may extend along an inner side surface of the fourth insulating layer 223b2.

The first bank 231 may be disposed on the fourth pixel electrode PEb2 and may have a fourth hole BH4 overlapping the third groove PG3, where the fourth hole BH4 may be smaller than the third groove PG3.

A fourth light-emitting layer EMLb2 may be disposed on the fourth pixel electrode PEb2.

Although not illustrated in FIG. 10, the common electrode CE may be disposed on the fourth light-emitting layer EMLb2 and may extend along an inner side surface of the fourth hole BH4 of the first bank 231 up to a top surface of the first bank 231 (or extend along an inner side surface of the first bank 231 up to a top surface of the first bank 231).

The display apparatus 110 according to embodiments of the present disclosure may further include the encapsulation layer 200 disposed on the first bank 231 and the common electrode CE, and a fourth color filter CF4 disposed on the encapsulation layer 200 and overlapping the fourth pixel electrode PEb2.

The fourth pixel electrode PEb2 may have a fourth inclined portion extending along an inner side surface of the fourth insulating layer 223b2.

The fourth color filter CF4 may overlap the fourth inclined portion.

A distance between a bottom surface of the second groove PG2 and a rear surface of the third insulating layer 223g2 may have a second thickness T2, and a distance between a bottom surface of the third groove PG3 and a rear surface of the fourth insulating layer 223b2 may have a third thickness T3 different from the second thickness T2.

The third sub-pixel SP3 may emit green light, the fourth sub-pixel SP4 may emit blue light, and the second thickness T2 may be greater than the third thickness T3.

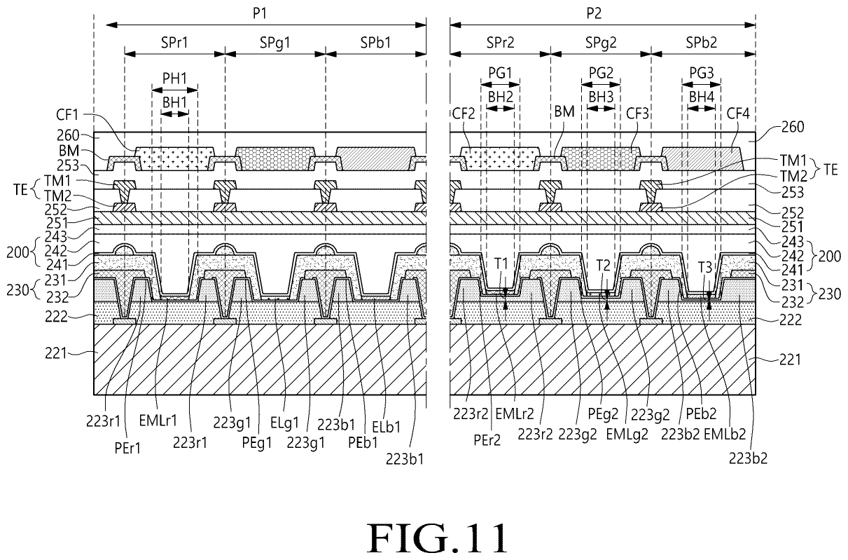

FIG. 11 illustrates a cross-sectional view of the first pixel P1 and the second pixel P2 of the display apparatus 110 according to embodiments of the present disclosure. The descriptions provided for elements in one or more figures (e.g., FIGS. 1-10) may apply to elements in other figures (e.g., FIG. 11) that use the same reference numerals unless stated otherwise.

Referring to FIG. 11, the first pixel P1 may include a first red sub-pixel SPr1, a first green sub-pixel SPg1, and a first blue sub-pixel SPb1. The second pixel P2 may include a second red sub-pixel SPr2, a second green sub-pixel SPg2, and a second blue sub-pixel SPb2.

Hereinafter, the first red sub-pixel SPr1 of the first pixel P1 may be referred to as the first sub-pixel SP1, and the second red sub-pixel SPr2, second green sub-pixel SPg2, and second blue sub-pixel SPb2 of the second pixel P2 may be referred to as the second sub-pixel SP2, the third sub-pixel SP3, and the fourth sub-pixel SP4, respectively.

The display apparatus 110 according to embodiments of the present disclosure may include the substrate 111. A first planarization layer 221 may be disposed on the substrate 111. A second planarization layer 222 may be disposed on the first planarization layer 221.

A first insulating layer 223r1 may be disposed on the second planarization layer 222 and located in an area of the first sub-pixel SP1, and may have a first opening PH1. A second insulating layer 223r2 may be disposed on the second planarization layer 222 and located in an area of the second sub-pixel SP2, and may have a first groove PG1.

A width of the first groove PG1 of the second sub-pixel SP2 may be smaller than a width of the first opening PH1 of the first sub-pixel SP1.

The first groove PG1 may have a depth smaller than that of the first opening PH1.

The first pixel electrode PEr1 may be disposed on the second planarization layer 222 in the first opening PH1, located in an area of the first sub-pixel SP1, and may extend along an inner side surface of the first insulating layer 223r1. The second pixel electrode PEr2 may be disposed on a bottom surface of the first groove PG1, located in an area of the second sub-pixel SP2, and may extend along an inner side surface of the first groove PG1.

The second bank 232 may be disposed on the first pixel electrode PEr1 and the second pixel electrode PEr2 and may be located outside the first opening PH1 and the first groove PG1.

The first bank 231 may be disposed on the first pixel electrode PEr1 and the second pixel electrode PEr2. The first bank 231 may have a first hole BH1 overlapping and smaller than the first opening PH1, and a second hole BH2 overlapping and smaller than the first groove PG1.

In the first sub-pixel SP1, a first separation distance D1 between an end of an inclined surface of the first bank 231 and an end of an inclined surface of the first insulating layer 223r1 may be greater than a second separation distance D2 between an end of an inclined surface of the first bank 231 and an end of an inclined surface of the second insulating layer 223r2 in the second sub-pixel SP2.

The second hole BH2 may have an area identical to an area of the first hole BH1.

A first light-emitting layer EMLr1 may be disposed on the first pixel electrode PEr1. A second light-emitting layer may be disposed on the second pixel electrode PEr2.

Although not illustrated in FIG. 11, the common electrode CE may be disposed on the first light-emitting layer EMLr1 and the second light-emitting layer EMLr2 and may extend along inner side surfaces of the first hole BH1 and the second hole BH2 of the first bank 231 up to a top surface of the first bank 231 (or extend along inner side surfaces of the first bank 231 up to a top surface of the first bank 231).

The display apparatus 110 according to embodiments of the present disclosure may further include the encapsulation layer 200 disposed on the first bank 231 and the common electrode CE, the first color filter CF1 disposed on the encapsulation layer 200 and overlapping the first pixel electrode PEr1, and a second color filter CF2 disposed on the encapsulation layer 200 and overlapping the second pixel electrode PEr2.

The first pixel electrode PEr1 may have a first inclined portion extending along an inner side surface of the first insulating layer 223r1, and the second pixel electrode PEr2 may have a second inclined portion extending along an inner side surface of the second insulating layer 223r2.

The first color filter CF1 may overlap the first inclined portion, and the second color filter CF2 may overlap the second inclined portion.

The first sub-pixel SP1 and the second sub-pixel SP2 may emit light of the same color, and the second color filter CF2 may have the same thickness as the first color filter CF1.

In the area of the third sub-pixel P3, the display apparatus 110 according to embodiments of the present disclosure may include a third insulating layer 223g2. The third insulating layer 223g2 may have a second groove PG2 and may be disposed on the second planarization layer 222. A third pixel electrode PEg2 may be disposed in the area of the third sub-pixel SP3 and disposed on the third insulating layer 223g2 in the second groove PG2 (or located at a bottom surface of the second groove PG2), extending along an inner side surface of the third insulating layer 223g2.

The second bank 232 may be disposed on the third pixel electrode PEg2 and located outside the second groove PG2.

The first bank 231 may be disposed on the third pixel electrode PEg2 and may have a third hole BH3 overlapping the second groove PG2 and smaller than the second groove PG2.

A third light-emitting layer EMLg2 may be disposed on the third pixel electrode PEg2.

Although not illustrated in FIG. 11, the common electrode CE may be disposed on the third light-emitting layer EMLg2 and may extend along an inner side surface of the third hole BH3 of the first bank 231 up to a top surface of the first bank 231 (or extend along an inner side surface of the first bank 231 up to a top surface of the first bank 231).

A distance between a bottom surface of the first groove PG1 and a rear surface of the second insulating layer 223r2 may have a first thickness T1, and a distance between a bottom surface of the second groove PG2 and a rear surface of the third insulating layer 223g2 may have a second thickness T2 different from the first thickness T1.

The second sub-pixel SP2 may emit red light, the third sub-pixel SP3 may emit green light, and the first thickness T1 may be greater than the second thickness T2.

In the area of the fourth sub-pixel SP4, the display apparatus 110 according to embodiments of the present disclosure may include a fourth insulating layer 223b2 disposed on the second planarization layer 222. A fourth pixel electrode PEb2 may be disposed in the area of the fourth sub-pixel SP4 and disposed on the fourth insulating layer 223b2 at the third groove PG3, extending along an inner side surface of the fourth insulating layer 223b2.

The first bank 231 may be disposed on the fourth pixel electrode PEb2 and may have a fourth hole BH4 overlapping the third groove PG3 and smaller than the third groove PG3.

A fourth light-emitting layer EMLb2 may be disposed on the fourth pixel electrode PEb2.

Although not illustrated in FIG. 11, the common electrode CE may be disposed on the fourth light-emitting layer EMLb2 and may extend along an inner side surface of the fourth hole BH4 of the first bank 231 up to a top surface of the first bank 231 (or extend along an inner side surface of the first bank 231 up to a top surface of the first bank 231).

A distance between a bottom surface of the first groove PG1 and a rear surface of the second insulating layer 223r2 may have a first thickness T1, and a distance between a bottom surface of the second groove PG2 and a rear surface of the third insulating layer 223g2 may have a second thickness T2 different from the first thickness T1.

The second sub-pixel SP2 may emit red light, the third sub-pixel SP3 may emit green light, and the first thickness T1 may be greater than the second thickness T2.

A distance between a bottom surface of the third groove PG3 and a rear surface of the fourth insulating layer 223b2 may have a third thickness T3 different from the second thickness T2.

The third sub-pixel SP3 may emit green light, the fourth sub-pixel SP4 may emit blue light, and the second thickness T2 may be greater than the third thickness T3.

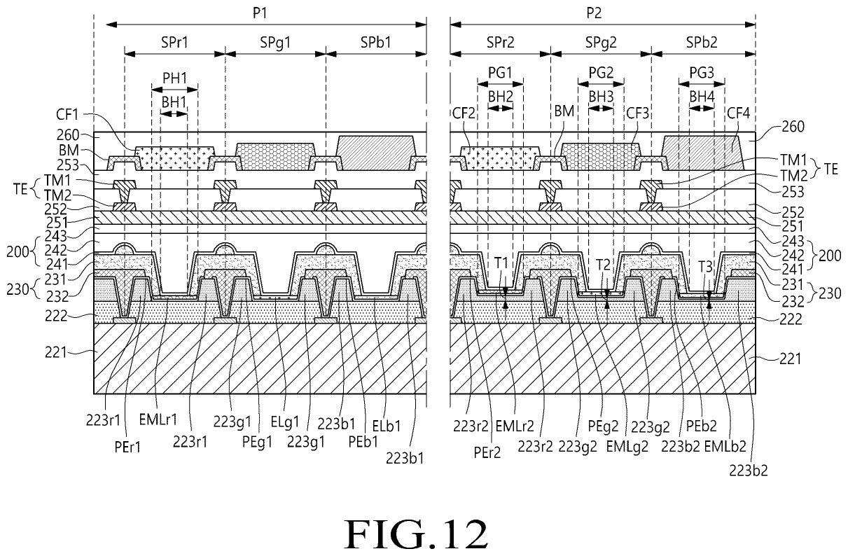

FIG. 12 illustrates a cross-sectional view of the first pixel P1 and the second pixel P2 of the display apparatus 110 according to embodiments of the present disclosure.

For contents substantially identical to those described with reference to FIG. 10, a detailed description thereof may be omitted. The descriptions provided for elements in one or more figures (e.g., FIG. 10) may apply to elements in other figures (e.g., FIG. 12) that use the same reference numerals unless stated otherwise.

The first sub-pixel SP1 and the second sub-pixel SP2 may emit light of different colors, and the first color filter CF1 may have a different thickness from the second color filter CF2.

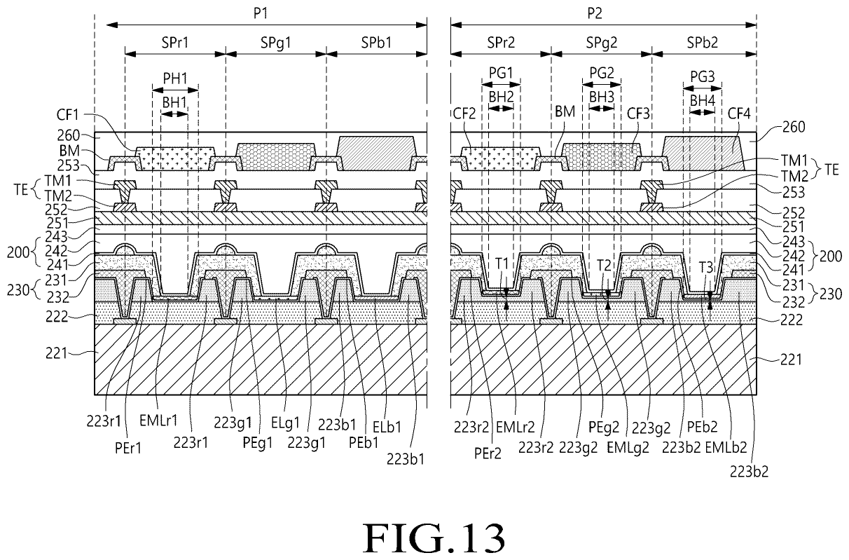

FIG. 13 illustrates a cross-sectional view of the first pixel P1 and the second pixel P2 of the display apparatus 110 according to embodiments of the present disclosure.

For contents substantially identical to those described with reference to FIG. 11, a detailed description thereof may be omitted. The descriptions provided for elements in one or more figures (e.g., FIG. 11) may apply to elements in other figures (e.g., FIG. 13) that use the same reference numerals unless stated otherwise.

The first sub-pixel SP1 and the second sub-pixel SP2 may emit light of different colors, and the first color filter CF1 may have a different thickness from the second color filter CF2.

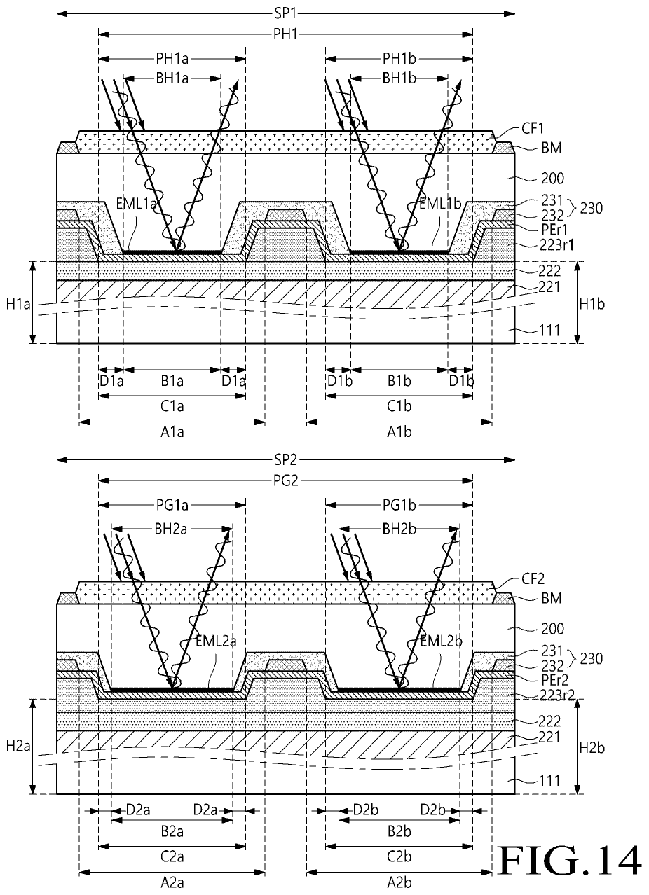

FIG. 14 illustrates a cross-sectional view of the first sub-pixel SP1 and the second sub-pixel SP2 of the display apparatus 110 according to embodiments of the present disclosure. The descriptions provided for elements in one or more figures (e.g., FIGS. 1-13) may apply to elements in other figures (e.g., FIG. 14) that use the same or similar reference numerals unless stated otherwise.

Referring to FIG. 14, the display apparatus 110 may include a first sub-pixel SP1 corresponding to a first color and a second sub-pixel SP2 corresponding to a second color. The first sub-pixel SP1 corresponding to the first color may denote that light having the first color is emitted from the light-emitting area located in the first sub-pixel SP1. The light-emitting area may include a region where a light-emitting layer is disposed and may further include a region where an inclined portion of the first pixel electrode PEr1 is located. Similarly, the second sub-pixel SP2 corresponding to the second color may denote that light having the second color is emitted from a light-emitting area located in the second sub-pixel SP2. The first color and the second color may be the same color. In such an example, the first sub-pixel SP1 may be a sub-pixel constituting the first pixel P1, and the second sub-pixel SP2 may be a sub-pixel constituting the second pixel P2.

In FIG. 14, the first opening PH1 may include a first sub-opening PH1a located in one area of the first sub-pixel SP1 and a second sub-opening PH1b located in another area of the first sub-pixel SP1. The first sub-opening PH1a and the second sub-opening PH1b of the first sub-pixel SP1 may correspond to main light-emitting areas in the first sub-pixel SP1. Thus, the first sub-pixel SP1 may include two main light-emitting areas. In this example, since the first sub-pixel SP1 corresponds to the first color, both of the two main light-emitting areas may emit light of the first color. By including two main light-emitting areas in the first sub-pixel SP1, it is possible to reduce color coordinate deviation toward the complementary color direction of the first color in the side viewing angle direction.

The first sub-pixel SP1 may include two openings. In this case, the first sub-opening PH1a and the second sub-opening PH1b may have substantially the same shape and area when viewed in a plane of the display area. Here, “substantially the same” may include minor differences within manufacturing tolerances.

The first insulating layer 223r1 may be further disposed between the first sub-opening PH1a and the second sub-opening PH1b. The first pixel electrode PEr1 may be disposed on the second planarization layer 222 in or at the areas of the first sub-opening PH1a and the second sub-opening PH1b, may extend beyond the outer boundaries of the first sub-opening PH1a and the second sub-opening PH1b, and may be disposed along inner side surfaces of the first insulating layer 223r1.

The first pixel electrode PEr1 may be disposed on the second planarization layer 222 within the first sub-opening PH1a and the second sub-opening PH1b, may extend beyond the outer boundaries of the first sub-opening PH1a and the second sub-opening PH1b, and may be disposed along inner side surfaces of the first insulating layer 223r1.

The first hole BH1 may include a first sub-hole BH1a located in one area of the first sub-pixel SP1 and a second sub-hole BH1b located in another area of the first sub-pixel SP1.

The first bank 231 and the second bank 232 may be further disposed between the first sub-hole BH1a and the second sub-hole BH1b.

The first light-emitting layer EMLr1 may include a first sub-light-emitting layer EML1a disposed in or at the first sub-hole BH1a and a second sub-light-emitting layer EML1b disposed in or at the second sub-hole BH1b.

The first groove PG1 in FIG. 14 may include a first sub-groove PG1a located in one area of the second sub-pixel SP2 and a second sub-groove PG1b located in another area of the second sub-pixel SP2. The first sub-groove PG1a and the second sub-groove PG1b of the second sub-pixel SP2 may each correspond to a main light-emitting area in the second sub-pixel SP2. Thus, the second sub-pixel SP2 may include two main light-emitting areas. In this example, since the second sub-pixel SP2 corresponds to the second color, both of the two main light-emitting areas may emit light of the second color. By including two main light-emitting areas in the second sub-pixel SP2, it is possible to reduce color coordinate deviation toward the complementary color direction of the second color in the side viewing angle direction.

The second sub-pixel SP2 may include two grooves. In this case, the first sub-groove PG1a and the second sub-groove PG1b may have substantially the same shape and area when viewed in a plane of the display area. Here, “substantially the same” may include minor differences within manufacturing tolerances.

The second insulating layer 223r2 may be further disposed between the first sub-groove PG1a and the second sub-groove PG1b. The second insulating layer 223r2 may have a top surface higher than bottom surfaces of the first sub-groove PG1a and the second sub-groove PG1b.

The second pixel electrode PEr2 may be disposed on the bottom surfaces of the first sub-groove PG1a and the second sub-groove PG2b, may extend beyond the outer boundaries of the first sub-groove PG1a and the second sub-groove PG2b, and may be disposed along inner side surfaces of the second insulating layer 223r2.

The second hole BH2 may include a third sub-hole BH2a located in one area of the second sub-pixel SP2 and a fourth sub-hole BH2b located in another area of the second sub-pixel SP2.

The first bank 231 and the second bank 232 may be further disposed between the third sub-hole BH2a and the fourth sub-hole BH2b.

The second light-emitting layer EMLr2 may include a third sub-light-emitting layer EML2a disposed in or at the third sub-hole BH2a and a fourth sub-light-emitting layer EML2b disposed in or at the fourth sub-hole BH2b.

The distance between the first pixel electrode PEr1 disposed in or at the first sub-opening PH1a and the substrate 111 may correspond to a first sub-height H1a, the distance between the first pixel electrode PEr1 disposed in or at the second sub-opening PH1b and the substrate 111 may correspond to a second sub-height H1b, the distance between the second pixel electrode PEr2 disposed in or at the first sub-groove PG1a and the substrate 111 may correspond to a third sub-height H2a, and the distance between the second pixel electrode PEr2 disposed in or at the second sub-groove PG1b and the substrate 111 may correspond to a fourth sub-height H2b. The first sub-height H1a and the second sub-height H1b may correspond to each other, and the third sub-height H2a and the fourth sub-height H2b may correspond to each other. In an example, the first sub-height H1a and the second sub-height H1b may be the same, and the third sub-height H2a and the fourth sub-height H2b may be the same.

At least one of the third sub-height H2a and the fourth sub-height H2b may be greater than each of the first sub-height H1a and the second sub-height H1b, and the first sub-height H1a and the second sub-height H1b may correspond to each other.

Each of the third sub-height H2a and the fourth sub-height H2b may be greater than each (or a respective one) of the first sub-height H1a and the second sub-height H1b, and the third sub-height H2a and the fourth sub-height H2b may correspond to each other.

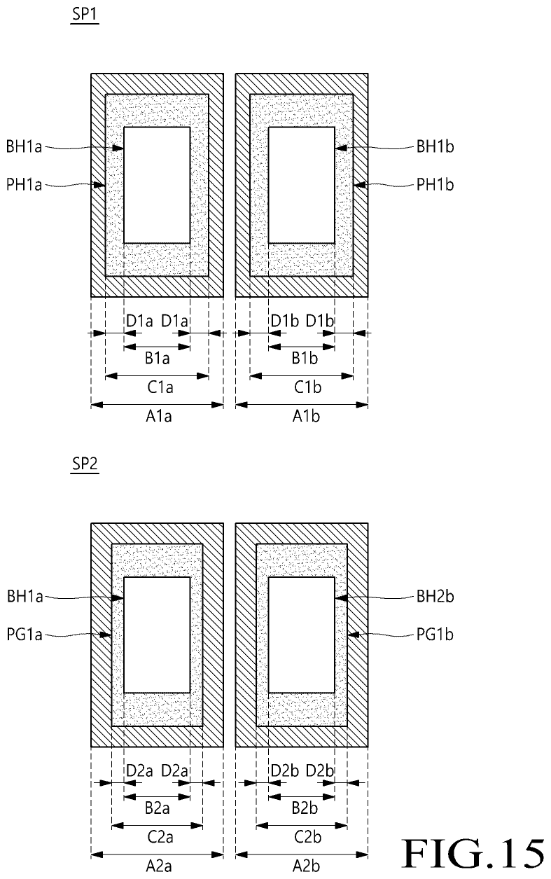

FIG. 15 illustrates a plan view of the first sub-pixel SP1 and the second sub-pixel SP2 of the display apparatus 110 according to embodiments of the present disclosure. The descriptions provided for elements in one or more figures (e.g., FIGS. 1-14) may apply to elements in other figures (e.g., FIG. 15) that use the same or similar reference numerals unless stated otherwise.

The areas of the first sub-opening PH1a and the second sub-opening PH1b may be the same.

The areas of the first sub-groove PG1a and the second sub-groove PG1b may be the same.

The area of the first sub-groove PG1a may be smaller than the area of the first sub-opening PH1a.

The area of the second sub-groove PG1b may be smaller than the area of the first sub-opening PH1b.

The width B1a of the first sub-hole BH1a may be the same as the width B1b of the second sub-hole BH1b.

The width B2a of the second sub-hole BH2a may be the same as the width B2b of the fourth sub-hole BH2b.

The width C1a of the first sub-opening PH1a may be the same as the width C1b of the second sub-opening PH1b.

The width C2a of the first sub-groove PG1a may be the same as the width C2b of the second sub-groove PG1b.

The width C2a of the first sub-groove PG1a may be smaller than the width C1a of the first sub-opening PH1a.

The width C2b of the second sub-groove PG1b may be smaller than the width C1b of the second sub-opening PH1b.

Each of the distances D2a and D2b between the end of the inclined surface of the first bank 231 and the end of the inclined surface of the second insulating layer 223r2 may be smaller than each of the distances D1a and D1b between the end of the inclined surface of the first bank 231 and the end of the inclined surface of the first insulating layer 223r1.

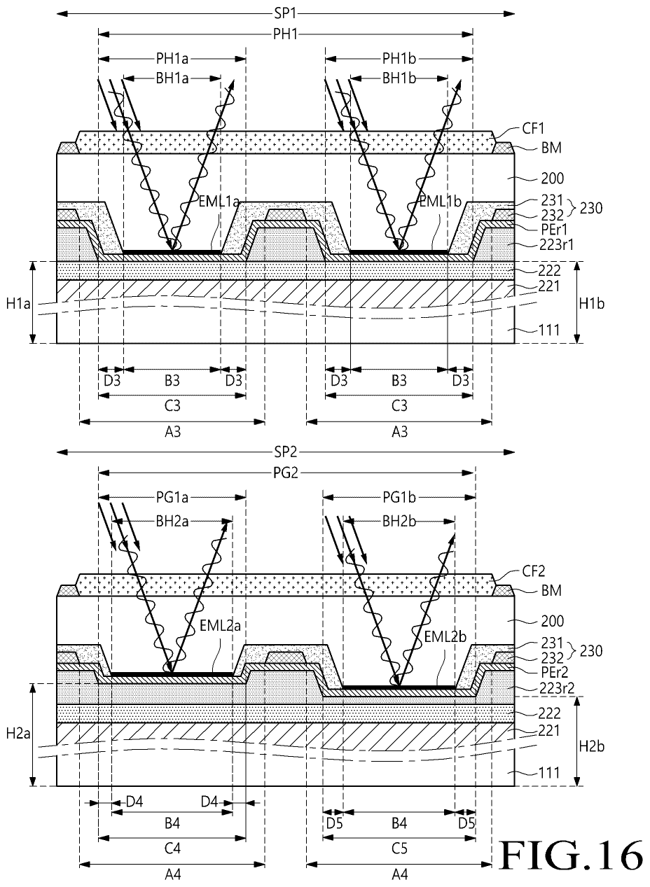

FIG. 16 illustrates a cross-sectional view of the first sub-pixel SP1 and the second sub-pixel SP2 of the display apparatus 110 according to embodiments of the present disclosure.

For contents substantially identical to those described with reference to FIG. 14, a detailed description thereof may be omitted. The descriptions provided for elements in one or more figures (e.g., FIGS. 1-15) may apply to elements in other figures (e.g., FIG. 16) that use the same or similar reference numerals unless stated otherwise.

The first opening PH1 may include a first sub-opening PH1a located in one area of the first sub-pixel SP1 and a second sub-opening PH1b located in another area of the first sub-pixel SP1.

The first groove PG1 may include a first sub-groove PG1a located in one area of the second sub-pixel SP2 and a second sub-groove PG1b located in another area of the second sub-pixel SP2.

The first hole BH1 may include a first sub-hole BH1a located in one area of the first sub-pixel SP1 and a second sub-hole BH1b located in another area of the first sub-pixel SP1.

The first light-emitting layer EMLr1 may include a first sub-light-emitting layer EML2a disposed in or at the first sub-hole BH1a and a second sub-light-emitting layer EML2b disposed in or at the second sub-hole BH1b, and the second hole BH2 may include a third sub-hole BH2a located in one area of the second sub-pixel SP2 and a fourth sub-hole BH2b located in another area of the second sub-pixel SP2.

The second light-emitting layer EMLr2 may include a third sub-light-emitting layer EML2a disposed in or at the third sub-hole BH2a and a fourth sub-light-emitting layer EML2b disposed in or at the fourth sub-hole BH2b.

The distance between the first pixel electrode PEr1 disposed in or at the first sub-opening PH1a and the substrate 111 may correspond to a first sub-height H1a, the distance between the first pixel electrode PEr1 disposed in or at the second sub-opening PH1b and the substrate 111 may correspond to a second sub-height H1b, the distance between the second pixel electrode PEr2 disposed in or at the first sub-groove PG1a and the substrate 111 may correspond to a third sub-height H2a, and the distance between the second pixel electrode PEr2 disposed in or at the second sub-groove PG1b and the substrate 111 may correspond to a fourth sub-height H2b. The first sub-height H1a and the second sub-height H1b may correspond to each other, and the third sub-height H2a and the fourth sub-height H2b may not necessarily correspond. In an example, the first sub-height H1a and the second sub-height H1b may be the same, and the third sub-height H2a and the fourth sub-height H2b may be different from each other.

At least one of the third sub-height H2a and the fourth sub-height H2b may be greater than each of the first sub-height H1a and the second sub-height H1b, and the first sub-height H1a and the second sub-height H1b may correspond to each other.

Each of the third sub-height H2a and the fourth sub-height H2b may be greater than each (or a respective one) of the first sub-height H1a and the second sub-height H1b, and the third sub-height H2a and the fourth sub-height H2b may not correspond to each other.

Each of the third sub-height H2a and the fourth sub-height H2b may be greater than each (or a respective one) of the first sub-height H1a and the second sub-height H1b, and the third sub-height H2a and the fourth sub-height H2b may be different.

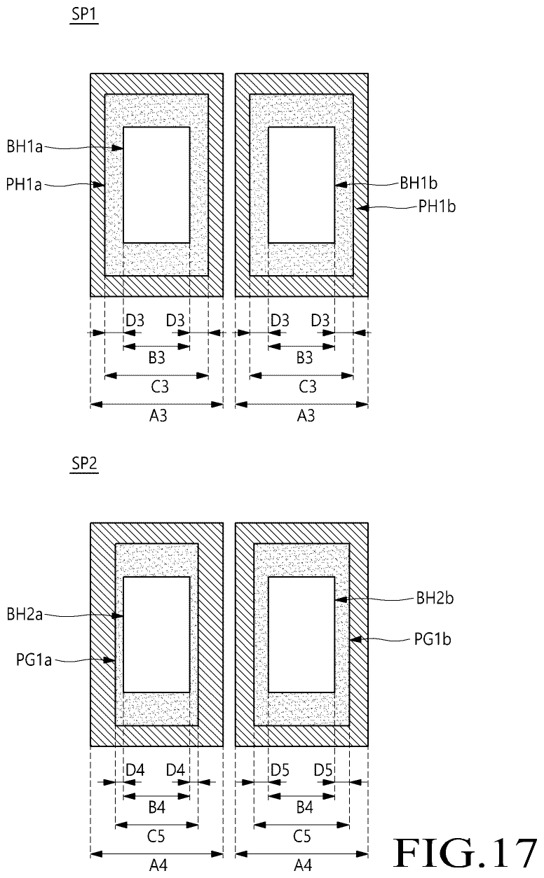

FIG. 17 illustrates a plan view of the first sub-pixel SP1 and the second sub-pixel SP2 of the display apparatus 110 according to embodiments of the present disclosure. The descriptions provided for elements in one or more figures (e.g., FIGS. 1-16) may apply to elements in other figures (e.g., FIG. 17) that use the same or similar reference numerals unless stated otherwise.

The areas of the first sub-opening PH1a and the second sub-opening PH1b may be the same.

The areas of the first sub-groove PG1a and the second sub-groove PG1b may not necessarily be the same.

The area of the first sub-groove PG1a may be smaller than the area of the first sub-opening PH1a.

The area of the second sub-groove PG1b may be smaller than the area of the second sub-opening PH1b.

The area of the first sub-groove PG1a may be smaller than the area of the second sub-groove PG1b.

The width B3 of the first sub-hole BH1a may be equal to the width B3 of the second sub-hole BH1b.

The width B4 of the third sub-hole BH2a may be equal to the width B4 of the fourth sub-hole BH2b.

The widths of the first sub-hole BH1a, the second sub-hole BH1b, the third sub-hole BH2a, and the fourth sub-hole BH2b may all be the same. B3 and B4 may be the same.

The width C3 of the first sub-opening PH1a may be the same as the width C3 of the second sub-opening PH1b.

The width C4 of the first sub-groove PG1a may not be the same as the width C5 of the second sub-groove PG1b.

The width C4 of the first sub-groove PG1a may be smaller than the width C3 of the first sub-opening PH1a.

The width C4 of the first sub-groove PG1a may be smaller than the width C3 of the second sub-opening PH1b.

Each of the distances D4 and D5 between the end of the inclined surface of the first bank 231 and the end of the inclined surface of the second insulating layer 223r2 may be smaller than the distance D3 between the end of the inclined surface of the first bank 231 and the end of the inclined surface of the first insulating layer 223r1.

Various examples and aspects of the present disclosure are described below. These are provided as examples, and do not limit the scope of the present disclosure.

A display apparatus according to embodiments of the present disclosure may include: a substrate; a first planarization layer disposed on the substrate; a second planarization layer disposed on the first planarization layer; a first insulating layer disposed on the second planarization layer, positioned in an area of a first sub-pixel, and having a first opening; a second insulating layer disposed on the second planarization layer, positioned in an area of a second sub-pixel, and having a first groove; a first pixel electrode positioned in the area of the first sub-pixel, disposed on the second planarization layer within the first opening, and extending along an inner sidewall of the first insulating layer; a second pixel electrode positioned in the area of the second sub-pixel, disposed on the bottom surface of the first groove, and extending along an inner sidewall of the first groove; a first bank disposed on the first and second pixel electrodes and having a first hole overlapping with but smaller than the first opening, and a second hole overlapping with but smaller than the first groove; a first light-emitting layer disposed on the first pixel electrode; a second light-emitting layer disposed on the second pixel electrode; and a common electrode disposed on the first and second light-emitting layers and extending along inner sidewalls of the first and second holes to the top surface of the first bank.

In the display apparatus according to embodiments of the present disclosure, the second hole may have the same area as the first hole.

The width of the first opening of the first sub-pixel may be the same as the width of the first groove of the second sub-pixel, and the first separation distance between the end of the inclined surface of the first bank and the end of the inclined surface of the first insulating layer in the first sub-pixel may be the same as the second separation distance between the end of the inclined surface of the first bank and the end of the inclined surface of the second insulating layer in the second sub-pixel.

The width of the first opening of the first sub-pixel may be greater than the width of the first groove of the second sub-pixel. The first spacing distance between an edge of the inclined surface of the first bank and an edge of the inclined surface of the first insulating layer in the first sub-pixel may be greater than the second spacing distance between an edge of the inclined surface of the first bank and an edge of the inclined surface of the second insulating layer in the second sub-pixel.

The first groove of the display apparatus according to embodiments of the present disclosure may have a smaller depth than the first opening.

The distance between the first pixel electrode disposed at the first opening and the substrate is the first height, the distance between the second pixel electrode disposed at the first groove and the substrate is the second height, and the second height is greater than the first height.

The display apparatus according to embodiments of the present disclosure may further include an encapsulation layer disposed on the common electrode; a first color filter disposed on the encapsulation layer and overlapping the first pixel electrode; and a second color filter disposed on the encapsulation layer and overlapping the second pixel electrode. The first pixel electrode may have a first inclined portion extending along the inner sidewall of the first insulating layer, and the second pixel electrode may have a second inclined portion extending along the inner sidewall of the second insulating layer. The first color filter may overlap the first inclined portion, and the second color filter may overlap the second inclined portion.

The first and second sub-pixels may emit light of different colors, and the first color filter may have a thickness different from that of the second color filter.

The first and second sub-pixels may emit light of the same color, and the first color filter may have the same thickness as the second color filter.

The area occupied by the first groove may be the same as the area occupied by the first opening.

The area occupied by the first groove may be smaller than the area occupied by the first opening.

The display apparatus according to embodiments of the present disclosure may further include a second bank disposed between the common electrode and the first pixel electrode and between the common electrode and the second pixel electrode, and positioned around the outer peripheries of the first opening and the first groove.

The display apparatus according to embodiments of the present disclosure may further include first to fourth pixels, wherein the first sub-pixel may be included in each of the first and third pixels, and the second sub-pixel may be included in each of the second and fourth pixels.

The distance between the first and third pixels may differ from the distance between the second and fourth pixels.

The display apparatus according to embodiments of the present disclosure may further include a third insulating layer disposed on the second planarization layer, positioned in an area of a third sub-pixel, and having a second groove; a third pixel electrode positioned in the area of the third sub-pixel, disposed on the third insulating layer in or at the second groove, and extending along an inner sidewall of the third insulating layer; the first bank disposed on the third pixel electrode and having a third hole overlapping but smaller than the second groove; a third light-emitting layer disposed on the third pixel electrode; and the common electrode disposed on the third light-emitting layer and extending along inner sidewalls of the third hole to the top surface of the first bank.

The distance between the bottom surface of the first groove and the rear surface of the second insulating layer may correspond to a first thickness, and the distance between the bottom surface of the second groove and the rear surface of the third insulating layer may correspond to a second thickness different from the first thickness.

The second sub-pixel may emit red light, the third sub-pixel may emit green light, and the first thickness may be greater than the second thickness.

The display apparatus according to embodiments of the present disclosure may further include a fourth insulating layer disposed on the second planarization layer, positioned in an area of a fourth sub-pixel, and having a third groove; a fourth pixel electrode positioned in the area of the fourth sub-pixel, disposed in the third groove on the fourth insulating layer, and extending along an inner sidewall of the fourth insulating layer; the first bank disposed on the fourth pixel electrode and having a fourth hole overlapping but smaller than the third groove; a fourth light-emitting layer disposed on the fourth pixel electrode; and the common electrode disposed on the fourth light-emitting layer and extending along respective inner sidewalls of the first bank to the top surface of the first bank.

The distance between the bottom surface of the third groove and the rear surface of the third insulating layer may have a third thickness different from the second thickness.

The third sub-pixel may emit green light, and the fourth sub-pixel may emit blue light, and the second thickness may be greater than the third thickness.

The first opening may include a first sub-opening positioned in a portion of the first sub-pixel and a second sub-opening positioned in another portion of the first sub-pixel. The first insulating layer may be disposed between the first and second sub-openings. The first pixel electrode may be disposed on the second planarization layer in the first and second sub-openings, may extend beyond the outer boundaries of the first and second sub-openings, and may be disposed along inner sidewalls of the first insulating layer. The first groove may include a first sub-groove positioned in a portion of the second sub-pixel and a second sub-groove positioned in another portion of the second sub-pixel. The second insulating layer may have an upper surface, between the first sub-groove and the second sub-groove, that is higher than the bottom surfaces of the first and second sub-grooves. The second pixel electrode may be disposed on the bottom surfaces of the first and second sub-grooves, may extend beyond the outer boundaries of the first and second sub-grooves, and may be disposed along inner sidewalls of the second insulating layer.

The first hole may include a first sub-hole positioned in the portion of the first sub-pixel and a second sub-hole positioned in the another portion of the first sub-pixel. The first bank may be further disposed between the first and second sub-holes. The first light-emitting layer may include a first sub-light-emitting layer disposed in the first sub-hole and a second sub-light-emitting layer disposed in the second sub-hole. The second hole may include a third sub-hole positioned in the portion of the second sub-pixel and a fourth sub-hole positioned in the another portion of the second sub-pixel. The first bank may be further disposed between the third and fourth sub-holes. The second light-emitting layer may include a third sub-light-emitting layer disposed in the third sub-hole and a fourth sub-light-emitting layer disposed in the fourth sub-hole.

The distance between the first pixel electrode disposed in the first sub-opening and the substrate may correspond to a first sub-height. The distance between the first pixel electrode disposed in the second sub-opening and the substrate may correspond to a second sub-height. The distance between the second pixel electrode disposed in the first sub-groove and the substrate may correspond to a third sub-height. The distance between the second pixel electrode disposed in the second sub-groove and the substrate may correspond to a fourth sub-height. The first and second sub-heights may correspond to each other, and at least one of the third and fourth sub-heights may be greater than each (or one) of the first and second sub-heights.

Each of the third and fourth sub-heights may be greater than each (or a respective one) of the first and second sub-heights, and the third and fourth sub-heights may correspond to each other.

Each of the third and fourth sub-heights may be greater than each (or a respective one) of the first and second sub-heights, and the third and fourth sub-heights may differ from each other.

A display apparatus according to embodiments of the present disclosure may include: a substrate; a first insulating layer disposed on the substrate, located in a first sub-pixel and having a first opening; a second insulating layer disposed on the substrate, located in a second sub-pixel and having a first groove; a first electrode located in the first sub-pixel, disposed at the first opening, and extending along an inner side surface of the first insulating layer; a second electrode located in the second sub-pixel, disposed at the first groove, and extending along an inner side surface of the second insulating layer; a first bank disposed on the first electrode and the second electrode and having a first hole and a second hole; a first light-emitting layer disposed between the first electrode and a third electrode; and a second light-emitting layer disposed on the second electrode. The first hole may overlap the first opening, and the second hole may overlap the first groove. A distance between the substrate and the second electrode at the first groove may be greater than a distance between the substrate and the first electrode at the first opening.

The first electrode may extend along an inner side surface of the first opening, and the second electrode may extend along an inner side surface of the first groove.

Each of the first opening and the first groove has an inclined side portion. Each of the first hole and the second hole has an inclined side portion.

The first light-emitting layer may be disposed at a bottom region of the first hole, and the second light-emitting layer may be disposed at a bottom region of the second hole. In an example, the first light-emitting layer does not extend upward along the inner side portion of the first hole. In an example, the second light-emitting layer does not extend upward along the inner side portion of the second hole.

A first gap may be provided between a lowermost edge of the first opening and a lowermost edge of the first hole that is closest to the lowermost edge of the first opening. A second gap may be provided between a lowermost edge of the first groove and a lowermost edge of the second hole that is closest to the lowermost edge of the first groove. The first gap may be greater than the second gap.

The description herein has been presented to enable any person skilled in the art to make, use and practice the technical features of the present disclosure, and has been provided in the context of one or more particular example applications and their example requirements. Various modifications, additions and substitutions to the described embodiments will be readily apparent to those skilled in the art, and the principles described herein may be applied to other embodiments and applications without departing from the scope of the present disclosure. The description herein and the accompanying drawings provide non-limiting examples of the technical features of the present disclosure for illustrative purposes. In other words, the disclosed embodiments illustrate the scope of the technical features of the present disclosure and are not intended to be limiting in any respect. Thus, the scope of the present disclosure is not limited to the embodiments shown, but is to be accorded the widest scope consistent with the claims and their equivalents.

What is claimed is:

1. A display apparatus, comprising:
a substrate;
a first planarization layer disposed on the substrate;
a second planarization layer disposed on the first planarization layer;
a first insulating layer disposed on the second planarization layer, located in a first sub-pixel area, and having a first opening;
a second insulating layer disposed on the second planarization layer, located in a second sub-pixel area, and having a first groove;
a first pixel electrode located in the first sub-pixel area, disposed on the second planarization layer at the first opening, and extending along an inner side surface of the first insulating layer;
a second pixel electrode located in the second sub-pixel area, disposed on a bottom surface of the first groove, and extending along an inner side surface of the first groove;
a first bank disposed on the first pixel electrode and the second pixel electrode and having a first hole and a second hole, wherein the first hole overlaps the first opening and is smaller than the first opening, and the second hole overlaps the first groove and is smaller than the first groove;
a first light-emitting layer disposed on the first pixel electrode;
a second light-emitting layer disposed on the second pixel electrode; and
a common electrode disposed on the first light-emitting layer and the second light-emitting layer, extending along respective inner side surfaces of the first hole and the second hole of the first bank up to a top surface of the first bank.

2. The display apparatus according to claim 1, wherein
a width of the first opening of the first sub-pixel area is greater than a width of the first groove of the second sub-pixel area, and
a first distance between an end of an inclined surface of the first bank and an end of an inclined surface of the first insulating layer in the first sub-pixel area is greater than a second distance between an end of an inclined surface of the first bank and an end of an inclined surface of the second insulating layer in the second sub-pixel area.

3. The display apparatus according to claim 1, wherein the first groove has a depth smaller than a depth of the first opening.

4. The display apparatus according to claim 1,
wherein a distance between the first pixel electrode disposed at the first opening and the substrate is a first height,
wherein a distance between the second pixel electrode disposed at the first groove and the substrate is a second height, and
wherein the second height is greater than the first height.

5. The display apparatus according to claim 1, further comprising:
an encapsulation layer disposed on the common electrode;
a first color filter disposed on the encapsulation layer and overlapping the first pixel electrode; and
a second color filter disposed on the encapsulation layer and overlapping the second pixel electrode,
wherein the first pixel electrode has a first inclined portion extending along the inner side surface of the first insulating layer,
wherein the second pixel electrode has a second inclined portion extending along an inner side surface of the second insulating layer,
wherein the first color filter overlaps the first inclined portion, and
wherein the second color filter overlaps the second inclined portion.

6. The display apparatus according to claim 5,
wherein the first sub-pixel area and the second sub-pixel area are configured to emit light of different colors, and
wherein the first color filter has a thickness different from a thickness of the second color filter.

7. The display apparatus according to claim 5,
wherein the first sub-pixel area and the second sub-pixel area are configured to emit light of a same color, and
wherein the first color filter has a same thickness as the second color filter.

8. The display apparatus according to claim 1, wherein an area occupied by the first groove is smaller than an area occupied by the first opening.

9. The display apparatus according to claim 1, further comprising a second bank disposed between the common electrode and the first pixel electrode and between the common electrode and the second pixel electrode, and located outside the first opening and the first groove.

10. The display apparatus according to claim 1, further comprising a first pixel, a second pixel, a third pixel, and a fourth pixel,
wherein the first sub-pixel area is included in each of the first pixel and the third pixel, wherein the second sub-pixel area is included in each of the second pixel and the fourth pixel, and
wherein a distance between the first pixel and the third pixel is different from a distance between the second pixel and the fourth pixel.

11. The display apparatus according to claim 1, further comprising:
a third insulating layer disposed on the second planarization layer, located in a third sub-pixel area, and having a second groove;
a third pixel electrode disposed in the third sub-pixel area, located on the third insulating layer at the second groove, and extending along an inner side surface of the third insulating layer; and
a third light-emitting layer disposed on the third pixel electrode,
wherein the first bank is disposed on the third pixel electrode, having a third hole overlapping the second groove and smaller than the second groove, and
wherein the common electrode is disposed on the third light-emitting layer and extending along an inner side surface of the third hole of the first bank up to a top surface of the first bank.

12. The display apparatus according to claim 11,
wherein a distance between the bottom surface of the first groove and a rear surface of the second insulating layer has a first thickness, and
wherein a distance between a bottom surface of the second groove and a rear surface of the third insulating layer has a second thickness different from the first thickness.

13. The display apparatus according to claim 12,
wherein the second sub-pixel area is configured to emit red light,
wherein the third sub-pixel area is configured to emit green light, and
wherein the first thickness is greater than the second thickness.

14. The display apparatus according to claim 12, further comprising:
a fourth insulating layer disposed on the second planarization layer, located in a fourth sub-pixel area, and having a third groove;
a fourth pixel electrode disposed in the fourth sub-pixel area, located on the fourth insulating layer at the third groove, and extending along an inner side surface of the fourth insulating layer; and
a fourth light-emitting layer disposed on the fourth pixel electrode,
wherein the first bank is disposed on the fourth pixel electrode, having a fourth hole overlapping the third groove and smaller than the third groove, and
wherein the common electrode is disposed on the fourth light-emitting layer and extending along an inner side surface of the fourth hole of the first bank up to a top surface of the first bank.

15. The display apparatus according to claim 14, wherein a distance between a bottom surface of the third groove and a rear surface of the fourth insulating layer has a third thickness different from the second thickness,
wherein the third sub-pixel area is configured to emit green light,
wherein the fourth sub-pixel area is configured to emit blue light, and
wherein the second thickness is greater than the third thickness.

16. The display apparatus according to claim 1,
wherein the first opening includes a first sub-opening located in one area of the first sub-pixel area and a second sub-opening located in another area of the first sub-pixel area,
wherein the first insulating layer is further disposed between the first sub-opening and the second sub-opening,
wherein the first pixel electrode is disposed on the second planarization layer at the first sub-opening and the second sub-opening, extends to outer sides of the first sub-opening and the second sub-opening, and is disposed along inner side surfaces of the first insulating layer,
wherein the first groove includes a first sub-groove located in one area of the second sub-pixel area and a second sub-groove located in another area of the second sub-pixel area,
wherein the second insulating layer has a top surface positioned higher than bottom surfaces of the first sub-groove and the second sub-groove and positioned between the first sub-groove and the second sub-groove, and
wherein the second pixel electrode is disposed on the bottom surfaces of the first sub-groove and the second sub-groove, extends to outer sides of the first sub-groove and the second sub-groove, and is disposed along inner side surfaces of the second insulating layer.

17. The display apparatus according to claim 16,
wherein the first hole includes a first sub-hole located in the one area of the first sub-pixel area and a second sub-hole located in the another area of the first sub-pixel area,
wherein the first bank is further disposed between the first sub-hole and the second sub-hole,
wherein the first light-emitting layer includes:
a first sub-light-emitting layer disposed in the first sub-hole; and
a second sub-light-emitting layer disposed in the second sub-hole,
wherein the second hole includes a third sub-hole located in the one area of the second sub-pixel area and a fourth sub-hole located in the another area of the second sub-pixel area,
wherein the first bank is further disposed between the third sub-hole and the fourth sub-hole, and
wherein the second light-emitting layer includes:
a third sub-light-emitting layer disposed in the third sub-hole; and
a fourth sub-light-emitting layer disposed in the fourth sub-hole.

18. The display apparatus according to claim 16,
wherein a distance between the first pixel electrode disposed at the first sub-opening and the substrate is a first sub-height,
wherein a distance between the first pixel electrode disposed at the second sub-opening and the substrate is a second sub-height,
wherein a distance between the second pixel electrode disposed at the first sub-groove and the substrate is a third sub-height,
wherein a distance between the second pixel electrode disposed at the second sub-groove and the substrate is a fourth sub-height,
wherein the first sub-height and the second sub-height correspond to each other, and
wherein at least one of the third sub-height and the fourth sub-height is greater than each of the first sub-height and the second sub-height.

19. The display apparatus according to claim 18, wherein each of the third sub-height and the fourth sub-height is greater than each of the first sub-height and the second sub-height, and
wherein the third sub-height and the fourth sub-height correspond to each other.

20. The display apparatus according to claim 18, wherein each of the third sub-height and the fourth sub-height is greater than each of the first sub-height and the second sub-height, and
wherein the third sub-height and the fourth sub-height are different from each other.
